(19) United States
(12) Patent Application Publication
(10) Pub. No.: US 2012/0200282 A1
(43) Pub. Date: Aug. 9, 2012

(54) CHIP ELECTRONIC COMPONENT, MOUNTED STRUCTURE OF CHIP ELECTRONIC COMPONENT, AND SWITCHING SUPPLY CIRCUIT

(75) Inventor: Masaaki TOGASHI, Tokyo (JP)

(73) Assignee: TDK CORPORATION, Tokyo (JP)

(21) Appl. No.: 13/348,203

(22) Filed: Jan. 11, 2012

(30) Foreign Application Priority Data
Feb. 7, 2011 (JP) 2011-024315

(51) Int. Cl. G05F 3/08; H01L 29/02; H01L 23/48

(52) U.S. Cl. 323/311; 257/734; 257/532; 257/E23.01; 257/E29.002

(57) ABSTRACT

A chip electronic component is provided with an element body containing a ferrite material; a first terminal electrode, a second terminal electrode, and a third terminal electrode arranged on the surface of the element body; and an internal conductor electrically connected to the first terminal electrode, the second terminal electrode, and the third terminal electrode. The impedance of a current path through the internal conductor between the first terminal electrode and the second terminal electrode is different from that of a current path through the internal conductor between the first terminal electrode and the third terminal electrode.

### BACKGROUND OF THE INVENTION

1. Field of the Invention

The present invention relates to a chip electronic component, a mounted structure of a chip electronic component, and a switching supply circuit.

2. Related Background Art

A ferrite chip bead inductor is known as a chip electronic component (e.g., cf. Japanese Utility Model Laid-open No. 55-145012). The ferrite chip bead inductor is provided with an element body containing a ferrite material, a pair of terminal electrodes arranged on the surface of the element body, and an internal conductor arranged in the element body. The internal conductor is electrically and physically connected to the pair of terminal electrodes.

### SUMMARY OF THE INVENTION

The ferrite chip bead inductor has the impedance which is naturally determined to be one value because of the aforementioned configuration. Therefore, in a situation in which the ferrite chip bead inductor is inserted at a location requiring control of impedance, e.g., at a point requiring different impedances, it is necessary to prepare a plurality of ferrite chip bead inductors with different impedances and insert each of the ferrite chip bead inductors. This leads to increase in the number of ferrite chip bead inductors needed.

An object of the present invention is to provide a chip electronic component, a mounted structure of a chip electronic component, and a switching supply circuit permitting easy and wide-range control of impedance, without increase in the number of parts.

A chip electronic component according to the present invention is a chip electronic component comprising: an element body containing a ferrite material; a first terminal electrode, a second terminal electrode, and a third terminal electrode arranged on a surface of the element body; and an internal conductor arranged in the element body and electrically connected to the first terminal electrode, the second terminal electrode, and the third terminal electrode, wherein an impedance of a current path through the internal conductor between the first terminal electrode and the second terminal electrode is different from an impedance of a current path through the internal conductor between the first terminal electrode and the third terminal electrode.

Since the element body contains the ferrite material in the chip electronic component according to the present invention, the chip electronic component functions as a ferrite chip bead inductor. The internal conductor is electrically connected to the first terminal electrode, the second terminal electrode, and the third terminal electrode and the impedance of the current path through the internal conductor between the first terminal electrode and the second terminal electrode is different from the impedance of the current path through the internal conductor between the first terminal electrode and the third terminal electrode. For this reason, for example, in the case where the first terminal electrode functions as an input terminal electrode and where the second and third terminal electrodes function as output terminal electrodes, the impedance of the current path between the input terminal electrode and one of the output terminal electrodes is different from the impedance of the current path between the input terminal electrode and the other output terminal electrode. In the present invention, the chip electronic component has at least two current paths with the different impedances. Accordingly, control of impedance can be performed readily and over a wide range, without increase in the number of parts.

The internal conductor may be physically connected to the first terminal electrode, the second terminal electrode, and the third terminal electrode. In this case, the impedance of the chip electronic component can be made smaller.

In the internal conductor, a length of the current path between the first terminal electrode and the second terminal electrode may be different from a length of the current path between the first terminal electrode and the third terminal electrode. In the internal conductor, a width of the current path between the first terminal electrode and the second terminal electrode may be different from a width of the current path between the first terminal electrode and the third terminal electrode. In either case, control of impedance can be performed easier and over a wider range.

The internal conductor may comprise a first internal conductor physically connected to the first terminal electrode and the second terminal electrode, and a second internal conductor physically connected to the second terminal electrode and the third terminal electrode, and the first terminal electrode and the third terminal electrode may be electrically connected through the first and second internal conductors and the second terminal electrode. In this case, the current path between the first terminal electrode and the third terminal electrode becomes relatively long. For this reason, control of impedance can be performed over a wider range.

The element body may have first and second principal faces of a nearly square shape opposed to each other, first and second side faces extending in a first-side direction of the first and second principal faces so as to connect the first and second principal faces, and opposed to each other, and third and fourth side faces extending in a second-side direction perpendicular to the first-side direction of the first and second principal faces so as to connect the first and second principal faces, and opposed to each other, and the first terminal electrode, the second terminal electrode, and the third terminal electrode may be arranged respectively on different side faces out of the first to fourth side faces. In this case, there is no directionality in mounting of the chip electronic component, which improves workability of mounting.

The element body may have first and second principal faces of a nearly rectangular shape opposed to each other, first and second side faces extending in a long-side direction of the first and second principal faces so as to connect the first and second principal faces, and opposed to each other, and third and fourth side faces extending in a short-side direction of the first and second principal faces so as to connect the first and second principal faces, and opposed to each other, and the first terminal electrode, the second terminal electrode, and the third terminal electrode may be arranged respectively on different side faces out of the first to fourth side faces. In this case, the impedance of the current path extending in the longitudinal direction of the element body becomes higher. Namely, the impedances of the current paths can be made different because of the shape of the element body.

The first terminal electrode, the second terminal electrode, and the third terminal electrode may be arranged on the same face of the element body. In this case, workability of mounting improves.

A mounted structure of a chip electronic component according to the present invention comprises the aforementioned chip electronic component, and a capacitor, and the chip electronic component and the capacitor are connected in series so that the first terminal electrode of the chip electronic component is located on the capacitor side.

The mounted structure of the chip electronic component according to the present invention comprises the aforementioned chip electronic component. This chip electronic component, as described above, has at least two current paths with the different impedances, and therefore permits easy and wide-range control of impedance, without increase in the number of parts.

Since the chip electronic component functioning as a ferrite chip bead inductor, and the capacitor are connected in series, a resistive component of the ferrite chip bead inductor (chip electronic component) acts as an Equivalent Series Resistance (ESR) of the capacitor. The resistive component of the ferrite chip bead inductor is composed of the sum of a DC resistance component and a loss which increases in a high frequency band. Therefore, the impedance increases in the high frequency band in this mounted structure, and therefore high-frequency noise can be suitably removed. The ferrite chip bead inductor functions as an inductor component rather than the resistive component in a low frequency band. For this reason, the impedance can be kept small in the low frequency band in the mounted structure. Since the capacitor is mounted, low-frequency noise is absorbed by the capacitor. As a result, the low-frequency noise can be suitably removed.

The present invention also provides a mounted structure of a chip electronic component in which the chip electronic component is inserted in a circuit, wherein the chip electronic component comprises an element body containing a ferrite material, and an internal conductor arranged in the element body, wherein the circuit comprises a first line, a second line, and a third line electrically connected to the internal conductor, and wherein an impedance of a current path through the internal conductor between the first line and the second line is different from an impedance of a current path through the internal conductor between the first line and the third line.

In the mounted structure of the chip electronic component according to the present invention, the chip electronic component has the element body containing the ferrite material, and therefore the chip electronic component functions as a ferrite chip bead inductor. The internal conductor is electrically connected to the first line, the second line, and the third line, and the impedance of the current path through the internal conductor between the first line and the second line is different from the impedance of the current path through the internal conductor between the first line and the third line. For this reason, for example, in the case where an electric current is input through the first line into the internal conductor and where the electric current is output from the internal conductor into the second line or the third line, the impedance of the current path between the first line and the second line is different from that of the current path between the first line and the third line. The mounted structure according to the present invention has at least two current paths with the different impedances. Therefore, it permits easy and wide-range control of impedance, without increase in the number of parts.

The chip electronic component may further comprise a first terminal electrode, a second terminal electrode, and a third terminal electrode physically connected to the internal conductor, the first terminal electrode may be physically connected to the first line, the second terminal electrode may be physically connected to the second line, and the third terminal electrode may be physically connected to the third line. In this case, the impedance of the chip electronic component can be made smaller.

In the internal conductor, a length of a current path between the first terminal electrode and the second terminal electrode may be different from a length of a current path between the first terminal electrode and the third terminal electrode. In the internal conductor, a width of the current path between the first terminal electrode and the second terminal electrode may be different from a width of the current path between the first terminal electrode and the third terminal electrode. In either case, control of impedance can be performed easier and over a wider range.

The internal conductor may comprise a first internal conductor physically connected to the first terminal electrode and the second terminal electrode, and a second internal conductor physically connected to the second terminal electrode and the third terminal electrode, and the first terminal electrode and the third terminal electrode may be electrically connected through the first and second internal conductors and the second terminal electrode. In this case, the current path between the first terminal electrode and the third terminal electrode becomes relatively long. For this reason, control of impedance can be performed over a wider range.

The chip electronic component may further comprise a first terminal electrode, a second terminal electrode, a third terminal electrode, and a fourth terminal electrode arranged on a surface of the element body, the internal conductor may comprise a first internal conductor physically connected to the first terminal electrode and the second terminal electrode, and a second internal conductor physically connected to the third terminal electrode and the fourth terminal electrode, the first terminal electrode may be physically connected to the first line, the second and third terminal electrodes may be physically connected to the second line, and the fourth terminal electrode may be physically connected to the third line. In this case, the first terminal electrode and the fourth terminal electrode are electrically connected through the first internal conductor, the second terminal electrode, the second line, the third terminal electrode, and the second internal conductor, and therefore a current path between the first terminal electrode and the fourth terminal electrode becomes relatively long. For this reason, control of impedance can be performed over a wider range.

A switching supply circuit according to the present invention is a switching supply circuit comprising: a first capacitor connected in parallel to a DC voltage source; a first transistor connected to a positive electrode of the DC voltage source; a second transistor connected between the first transistor and a negative electrode of the DC voltage source and brought into a conductive state, alternating with the first transistor; the aforementioned chip electronic component which is inserted at a midpoint between the first transistor and the second transistor; an inductor one end of which is connected to the chip electronic component; and a second capacitor one end of which is connected to the other end of the inductor and the other end of which is connected to the negative electrode of the DC voltage source, wherein the first transistor is connected to the first terminal electrode of the chip electronic component, wherein the second transistor is connected to the third terminal electrode of the chip electronic component, wherein the one end of the inductor is connected to the second terminal electrode of the chip electronic component, and wherein the impedance of the current path through the internal conductor between the first terminal electrode and the third terminal electrode is higher than the impedance of the current path through the internal conductor between the first terminal electrode and the second terminal electrode.

The switching supply circuit according to the present invention comprises the aforementioned chip electronic component. The chip electronic component has at least two current paths with the different impedances, as described above. For this reason, control of impedance can be performed readily and over a wide range, without increase in the number of parts, in the switching supply circuit according to the present invention.

Since in the switching supply circuit the first capacitor is connected in parallel to the DC voltage source, resonance could occur in a loop consisting of the first capacitor, the first transistor, and the second transistor. This resonance phenomenon induces an overshoot or an undershoot in the output from each transistor. The overshoot or the undershoot occurring in the output can be a cause of electromagnetic noise.

In the switching supply circuit according to the present invention, the aforementioned chip electronic component is inserted at the midpoint between the first transistor and the second transistor. For this reason, the impedance of the current path through the internal conductor between the first terminal electrode and the third terminal electrode is higher than the impedance of the current path through the internal conductor between the first terminal electrode and the second terminal electrode. Since the current path consisting of the first terminal electrode, the internal conductor, and the third terminal electrode is inserted in the loop consisting of the first capacitor, the first transistor, and the second transistor, the impedance of the loop becomes high enough to suppress occurrence of resonance in the loop. As a consequence, the switching supply circuit according to the present invention can suppress occurrence of electromagnetic noise.

Since the chip electronic component is inserted at the midpoint between the first transistor and the second transistor, the current path consisting of the first terminal electrode, the internal conductor, and the second terminal electrode is inserted in a power supply line to a load. For this reason, the impedance of the current path consisting of the first terminal electrode, the internal conductor, and the second terminal electrode is lower than that of the current path consisting of the first terminal electrode, the internal conductor, and the third terminal electrode. Therefore, consumption of power can be suppressed in the current path consisting of the first terminal electrode, the internal conductor, and the second terminal electrode.

A switching supply circuit according to the present invention is a switching supply circuit comprising: a first capacitor connected in parallel to a DC voltage source; a first transistor connected to a positive electrode of the DC voltage source; a second transistor connected between the first transistor and a negative electrode of the DC voltage source and brought into a conductive state, alternating with the first transistor; a chip electronic component inserted at a midpoint between the first transistor and the second transistor; an inductor one end of which is connected to the chip electronic component; and a second capacitor one end of which is connected to the other end of the inductor and the other end of which is connected to the negative electrode of the DC voltage source, wherein the chip electronic component has: an element body containing a ferrite material; a first terminal electrode, a second terminal electrode, a third terminal electrode, and a fourth terminal electrode arranged on a surface of the element body; a first internal conductor arranged in the element body and physically connected to the first terminal electrode and the second terminal electrode; and a second internal conductor arranged in the element body and physically connected to the third terminal electrode and the fourth terminal electrode, wherein the first transistor is connected to the first terminal electrode of the chip electronic component, wherein the second transistor is connected to the fourth terminal electrode of the chip electronic component, and wherein the one end of the inductor is connected to the second and third terminal electrodes of the chip electronic component.

In the switching supply circuit according to the present invention, the first terminal electrode and the fourth terminal electrode in the chip electronic component are electrically connected through the first internal conductor, the second terminal electrode, a connection point to the inductor, the third terminal electrode, and the second internal conductor. For this reason, the current path between the first terminal electrode and the fourth terminal electrode becomes relatively long. Therefore, control of impedance can be performed over a wider range.

In the switching supply circuit according to the present invention, the current path between the first terminal electrode and the fourth terminal electrode is inserted in a loop consisting of the first capacitor, the first transistor, and the second transistor. For this reason, the impedance of the loop becomes high enough to suppress occurrence of resonance in the loop. Therefore, it is feasible to suppress occurrence of electromagnetic noise.

The current path consisting of the first terminal electrode, the first internal conductor, and the second terminal electrode is inserted in a power supply line to a load. The impedance of the current path consisting of the first terminal electrode, the first internal conductor, and the second terminal electrode is lower than that of the current path between the first terminal electrode and the fourth terminal electrode. For this reason, it is feasible to suppress consumption of power in the current path consisting of the first terminal electrode, the first internal conductor, and the second terminal electrode.

A switching supply circuit according to the present invention is a switching supply circuit comprising: a first capacitor connected in parallel to a DC voltage source; the chip electronic component as set forth in claim 1, which is inserted in series to the first capacitor; a first transistor connected to a positive electrode of the DC voltage source; a second transistor connected between the first transistor and a negative electrode of the DC voltage source and brought into a conductive state, alternating with the first transistor; an inductor one end of which is connected to a midpoint between the first transistor and the second transistor; and a second capacitor one end of which is connected to the other end of the inductor and the other end of which is connected to the negative electrode of the DC voltage source, wherein the first capacitor is connected to the first terminal electrode of the chip electronic component, and wherein at least one terminal electrode out of the second and third terminal electrodes of the chip electronic component is connected to the negative electrode of the DC voltage source.

The switching supply circuit according to the present invention comprises the aforementioned chip electronic component. Since the chip electronic component has at least two current paths with the different impedances as described above, it can perform easy and wide-range control of impedance, without increase in the number of parts.

In the switching supply circuit according to the present invention, the chip electronic component is inserted in a loop consisting of the first capacitor, the first transistor, and the second transistor, the impedance of the loop is therefore high enough to suppress occurrence of resonance in the loop. Accordingly, occurrence of electromagnetic noise can be suppressed. The value of impedance inserted in the loop can be adjusted by changing the number of terminal electrodes to be connected to the negative electrode of the DC voltage source, in the chip electronic component.

The present invention will become more fully understood from the detailed description given hereinbelow and the accompanying drawings which are given by way of illustration only, and thus are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a perspective view showing a chip electronic component according to the first embodiment.

FIG. 2 is an exploded perspective view showing configurations of an element body and internal conductors.

FIG. 3 is a drawing for explaining current paths.

FIG. 4 is a drawing for explaining current paths.

FIG. 5 is a perspective view showing a chip electronic component according to the second embodiment.

FIG. 6 is an exploded perspective view showing configurations of an element body and internal conductors.

FIG. 7 is a drawing for explaining current paths.

FIG. 8 is a drawing for explaining current paths.

FIG. 9 is an exploded perspective view showing a modification example of the chip electronic component according to the second embodiment.

FIG. 10 is a perspective view showing a chip electronic component according to the third embodiment.

FIG. 11 is an exploded perspective view showing configurations of an element body and internal conductors.

FIG. 12 is a drawing for explaining current paths.

FIG. 13 is a perspective view showing a chip electronic component according to the fourth embodiment.

FIG. 14 is an exploded perspective view showing configurations of an element body and internal conductors.

FIG. 15 is a drawing for explaining current paths.

FIG. 16 is a perspective view showing a chip electronic component according to the fifth embodiment.

FIG. 17 is an exploded perspective view showing configurations of an element body and internal conductors.

FIG. 18 is a drawing for explaining current paths.

FIG. 19 is a perspective view showing a modification example of the chip electronic component according to the fifth embodiment.

FIG. 20 is an exploded perspective view showing configurations of an element body and internal conductors.

FIG. 21 is a perspective view showing a modification example of the chip electronic component according to the fifth embodiment.

FIG. 22 is an exploded perspective view showing configurations of an element body and internal conductors.

FIG. 23 is a drawing for explaining a mounted structure of a chip electronic component according to the sixth embodiment.

FIG. 24 is a drawing for explaining a mounted structure of a chip electronic component according to the seventh embodiment.

FIG. 25 is a perspective view showing the chip electronic component.

FIG. 26 is an exploded perspective view showing configurations of an element body and internal conductors.

FIG. 27 is a drawing for explaining current paths.

FIG. 28 is an exploded perspective view for explaining a modification example of the chip electronic component.

FIG. 29 is an exploded perspective view for explaining a modification example of the chip electronic component.

FIG. 30 is an exploded perspective view for explaining a modification example of the chip electronic component.

FIG. 31 is a drawing for explaining current paths in the modification example of the mounted structure of the chip electronic component according to the seventh embodiment.

FIG. 32 is a drawing for explaining a mounted structure of a chip electronic component according to the eighth embodiment.

FIG. 33 is a drawing for explaining modification examples of the mounted structure of the chip electronic component according to the eighth embodiment.

FIG. 34 is a drawing for explaining modification examples of the mounted structure of the chip electronic component according to the eighth embodiment.

FIG. 35 is a drawing showing a configuration of a switching supply circuit according to the ninth embodiment.

FIG. 36 is a drawing showing a configuration of a modification example of the switching supply circuit according to the ninth embodiment.

FIG. 37 is a drawing showing a configuration of a modification example of the switching supply circuit according to the ninth embodiment.

FIG. 38 is a drawing showing a configuration of a modification example of the switching supply circuit according to the ninth embodiment.

FIG. 39 is a drawing showing a configuration of a switching supply circuit according to the tenth embodiment.

FIG. 40 is a drawing showing a configuration of a switching supply circuit according to the tenth embodiment.

FIG. 41 is a drawing showing a configuration of a switching supply circuit according to the tenth embodiment.

FIG. 42 is a drawing showing a configuration of a switching supply circuit according to the eleventh embodiment.

FIG. 43 is a drawing showing a configuration of a switching supply circuit according to the eleventh embodiment.

### DESCRIPTION OF THE PREFERRED EMBODIMENTS

The preferred embodiments of the present invention will be described below in detail with reference to the accompanying drawings. In the description, the same elements or elements with the same functionality will be denoted by the same reference signs, without redundant description.

### First Embodiment

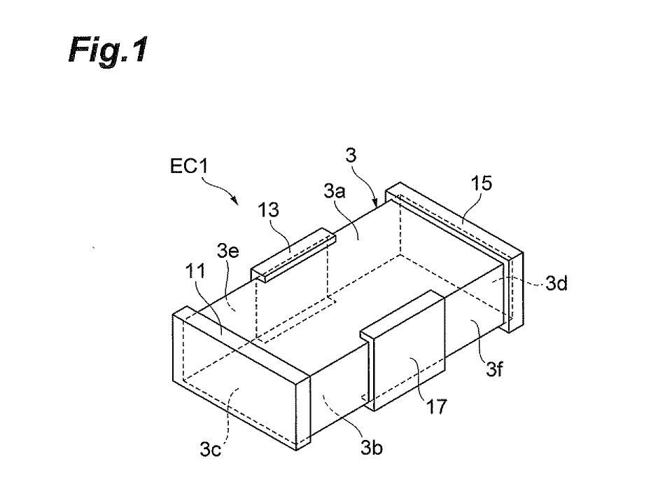

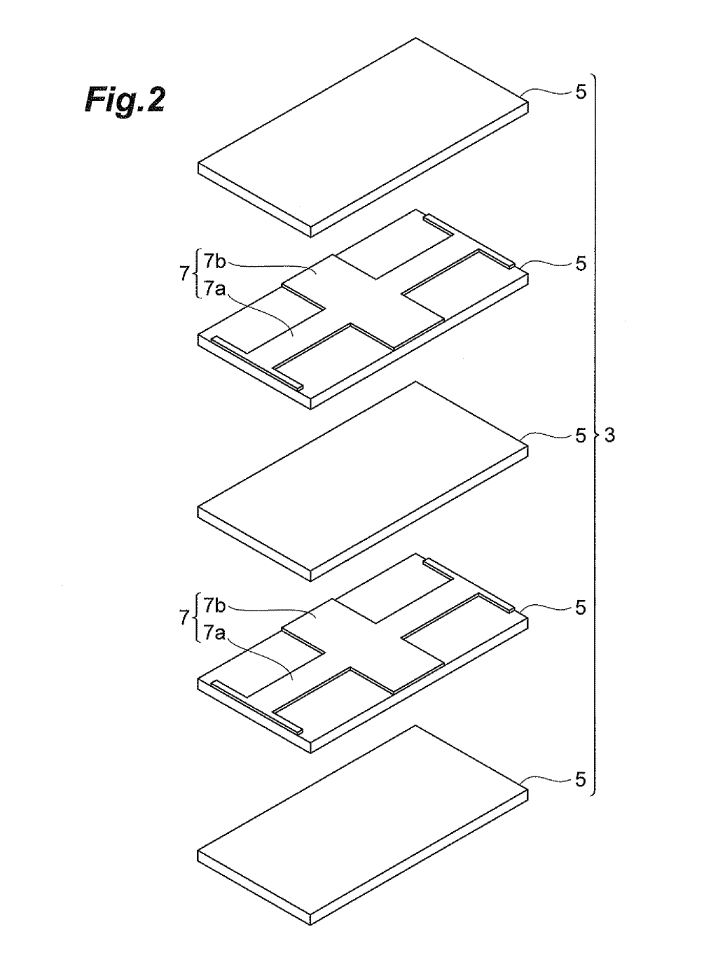

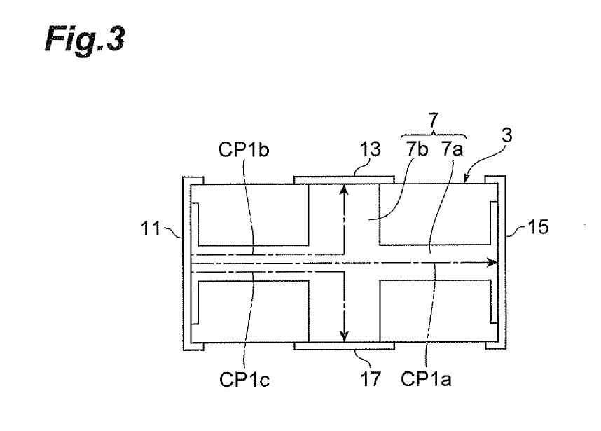

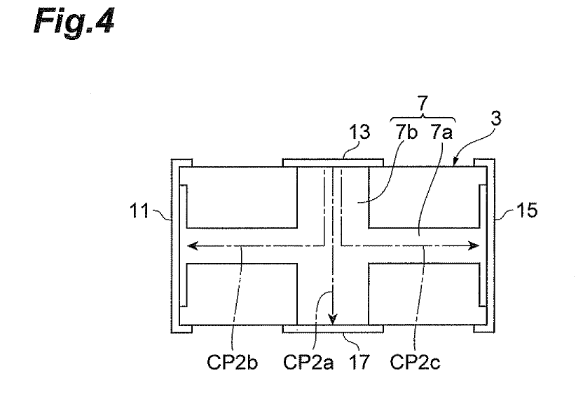

First, a configuration of a chip electronic component EC1 according to the first embodiment will be described with reference to FIGS. 1 to 4. FIG. 1 is a perspective view showing the chip electronic component according to the first embodiment. FIG. 2 is an exploded perspective view showing configurations of an element body and internal conductors. FIGS. 3 and 4 are drawings for explaining current paths.

The chip electronic component EC1, as shown in FIG. 1, is provided with an element body 3, a first terminal electrode 11, a second terminal electrode 13, a third terminal electrode 15, and a fourth terminal electrode 17.

The element body 3 is of a nearly rectangular parallelepiped shape and has a first principal face 3a, a second principal face 3b, a first side face 3c, a second side face 3d, a third side face 3e, and a fourth side face 3f. The first and second principal faces 3a, 3b are opposed to each other and are of a nearly rectangular shape. The first and second side faces 3c, 3d extend in the short-side direction of the first and second principal faces 3a, 3b so as to connect the first and second principal faces 3a, 3b and are opposed to each other. The third and fourth side faces 3e, 3f extend in the long-side direction of the first and second principal faces 3a, 3b so as to connect the first and second principal faces 3a, 3b and are opposed to each other.

The element body 3, as shown in FIG. 2, has a plurality of insulator layers 5. The element body 3 is composed of the plurality of insulator layers 5 stacked in the direction in which the first principal face 3a and the second principal face 3b are opposed. Each insulator layer 5 is composed of a sintered body of a green sheet containing a ferrite (e.g., Ni—Cu—Zn ferrite, Ni—Cu—Zn—Mg ferrite, Cu—Zn ferrite, or Ni—Cu ferrite) material. In the actual chip electronic component EC1, the insulator layers 5 are integrally formed so that no boundary can be visually recognized between them.

The first terminal electrode 11 is arranged on the first side face 3c. The second terminal electrode 13 is arranged in a central region in the long-side direction of the first and second principal faces 3a, 3b, on the third side face 3e. The third terminal electrode 15 is arranged on the second side face 3d. The fourth terminal electrode 17 is arranged in a central region in the long-side direction of the first and second principal faces 3a, 3b, on the fourth side face 3f. The first terminal electrode 11 and the third terminal electrode 15 are opposed to each other in the long-side direction of the first and second principal faces 3a, 3b (the longitudinal direction of the element body 3). The second terminal electrode 13 and the fourth terminal electrode 17 are opposed to each other in the short-side direction of the first and second principal faces 3a, 3b (the transverse direction of the element body 3).

The first to fourth terminal electrodes 11-17 are formed, for example, by applying an electroconductive paste containing an electroconductive metal powder and a glass fit, onto the exterior surface of the element body 3 and sintering it. A plated layer can be optionally formed on the first to fourth terminal electrodes 11-17 thus formed, as occasion demands.

The chip electronic component EC1, as shown in FIG. 2, is provided with internal conductors 7. Each of the internal conductors 7 has a conductor portion 7a extending in the long-side direction of the first and second principal faces 3a, 3b, and a conductor portion 7b extending in the short-side direction of the first and second principal faces 3a, 3b. The internal conductors 7 are comprised of an electroconductive material (e.g., Ag) which is usually used for internal electrodes of multilayer electric elements. Each internal conductor 7 is composed of a sintered body of an electroconductive paste containing the foregoing electroconductive material.

The conductor portion 7a has its ends exposed in the first and second side faces 3c, 3d, respectively. The conductor portion 7a is physically and electrically connected to the first and third terminal electrodes 11, 15. The ends of the conductor portion 7a are widened in order to achieve secure connections to the first and third terminal electrodes 11, 15. The conductor portion 7b has its ends exposed in the third and fourth side faces 3e, 3f, respectively. The conductor portion 7b is physically and electrically connected to the second and fourth terminal electrodes 13, 17. This configuration makes the internal conductors 7 physically and electrically connected to the first to fourth terminal electrodes 11-17. The length of the conductor portion 7a is set longer than the length of the conductor portion 7b. The width of the conductor portion 7a is set smaller than the width of the conductor portion 7b.

The below will describe current paths in the chip electronic component EC1, with reference to FIGS. 3 and 4.

In the chip electronic component EC1 shown in FIG. 3, for example, the first terminal electrode 11 functions as an input terminal electrode and the second to fourth terminal electrodes 13-17 function as output terminal electrodes. In this case, there are three current paths CP1a-CP1c formed in the chip electronic component EC1. The current path CP1a is a current path through the internal conductors 7 (conductor portions 7a) between the first terminal electrode 11 and the third terminal electrode 15. The current path CP1b is a current path through the internal conductors 7 (conductor portions 7a, 7b) between the first terminal electrode 11 and the second terminal electrode 13. The current path CP1c is a current path through the internal conductors 7 (conductor portions 7a, 7b) between the first terminal electrode 11 and the fourth terminal electrode 17. The current path CP1a has the impedance higher than the current paths CP1b, CP1c because the conductor portion 7a is longer and narrower than the conductor portion 7b.

In the chip electronic component EC1 shown in FIG. 4, for example, the second terminal electrode 13 functions as an input terminal electrode and the first terminal electrode 11, the third terminal electrode 15, and the fourth terminal electrode 17 function as output terminal electrodes. In this case, there are three current paths CP2a-CP2c formed in the chip electronic component EC1. The current path CP2a is a current path through the internal conductors 7 (conductor portions 7b) between the second terminal electrode 13 and the fourth terminal electrode 17. The current path CP2b is a current path through the internal conductors 7 (conductor portions 7a, 7b) between the second terminal electrode 13 and the first terminal electrode 11. The current path CP2c is a current path through the internal conductors 7 (conductor portions 7a, 7b) between the second terminal electrode 13 and the third terminal electrode 15. The current path CP2a has the impedance lower than the current paths CP2b, CP2c because the conductor portion 7b is shorter and wider than the conductor portion 7a.

In the present embodiment, as described above, the chip electronic component EC1 functions as a ferrite chip bead inductor because the element body 3 contains the ferrite material. The internal conductors 7 are electrically connected to the first to fourth terminal electrodes 11-17 and the current path CP1a has the higher impedance than the current paths CP1b, CP1c. The current path CP2a has the lower impedance than the current paths CP2b, CP2c. The current path CP1a has the higher impedance than the current path CP2a. In this manner, the chip electronic component EC1 has the plurality of current paths with the different impedances (e.g., the current paths CP1a-CP1c, CP2a-CP2c). Therefore, the chip electronic component EC1 allows easy and wide-range control of impedance, without increase in the number of parts.

In the present embodiment, the internal conductors 7 are physically connected to the first to fourth terminal electrodes 11-17. This configuration decreases the impedance of the chip electronic component EC1.

In the present embodiment, the length of the conductor portion 7a is different from the length of the conductor portion 7b. This makes the length of the current path between the first terminal electrode 11 and the second terminal electrode 13 different from the length of the current path between the first terminal electrode 11 and the third terminal electrode 15, in the internal conductors 7. In the internal conductors 7, the length of the current path between the first terminal electrode 11 and the second terminal electrode 13 is also different from the length of the current path between the second terminal electrode 13 and the fourth terminal electrode 17. As a result of these, the chip electronic component EC1 permits easier and wider-range control of impedance.

In the present embodiment, the width of the conductor portion 7a is different from the with of the conductor portion 7b. This makes the width of the current path between the first terminal electrode 11 and the second terminal electrode 13 different from the width of the current path between the first terminal electrode 11 and the third terminal electrode 15, in the internal conductors 7. In the internal conductors 7, the width of the current path between the first terminal electrode 11 and the second terminal electrode 13 is also different from the width of the current path between the second terminal electrode 13 and the fourth terminal electrode 17. As a result of these, the chip electronic component EC1 permits easier and wider-range control of impedance.

In the present embodiment, the element body 3 has the first and second principal faces 3a, 3b, the first and second side faces 3c, 3d, and the third and fourth side faces 3e, 3f and the first to fourth terminal electrodes 11-17 are arranged on the different side faces, respectively. This increases the impedance of the current path CP1a extending in the longitudinal direction of the element body 3. Namely, the impedances of the current paths CP1a-CP1c, CP2a-CP2c can be made different by the shape of the element body 3.

### Second Embodiment

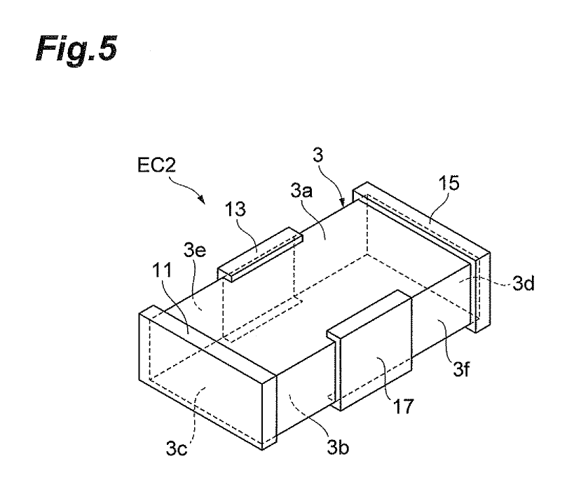

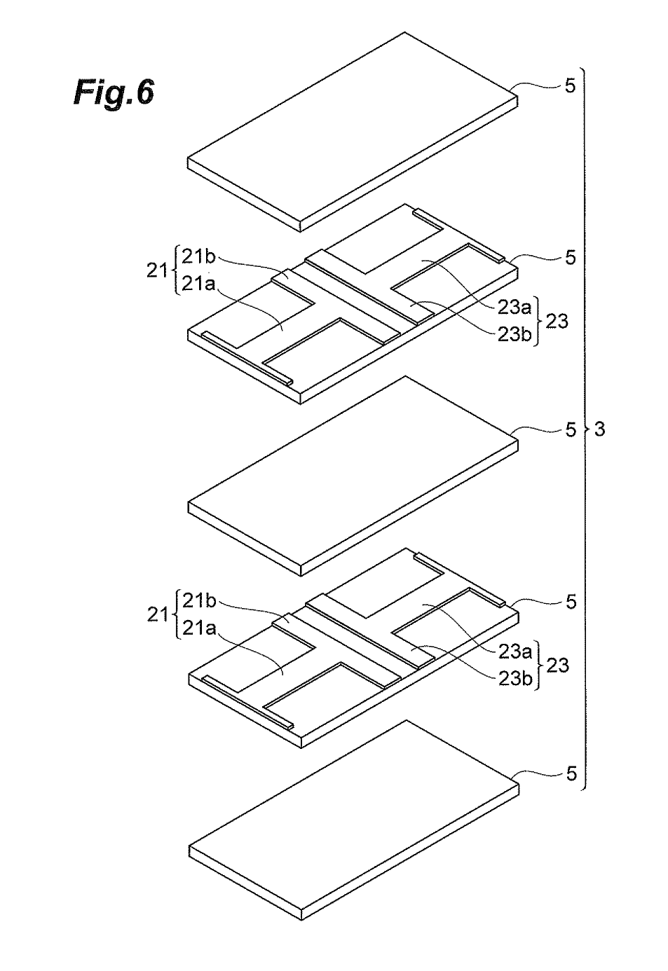

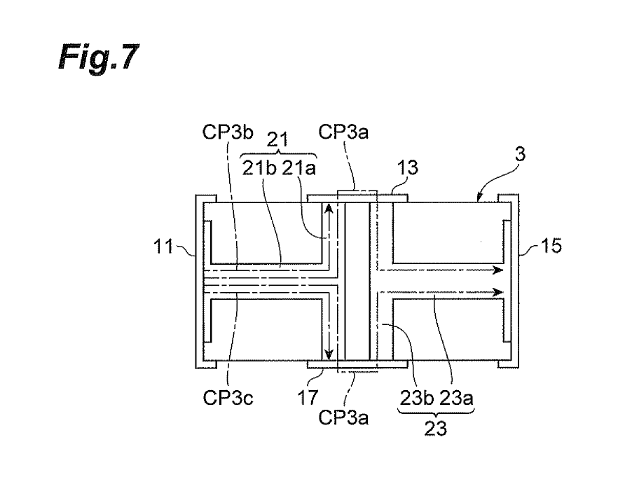

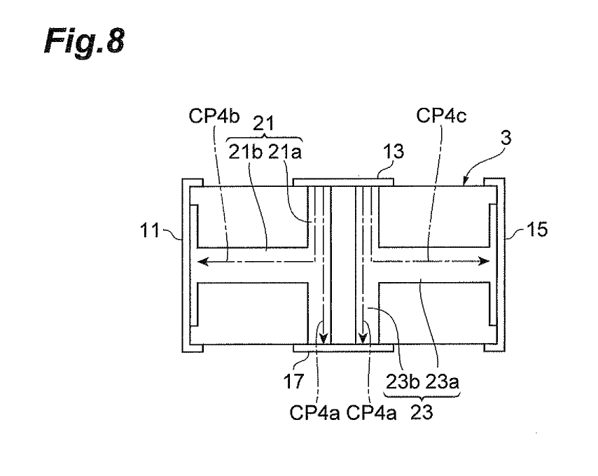

A configuration of a chip electronic component EC2 according to the second embodiment will be described below with reference to FIGS. 5 to 8. FIG. 5 is a perspective view showing the chip electronic component according to the second embodiment. FIG. 6 is an exploded perspective view showing configurations of an element body and internal conductors. FIGS. 7 and 8 are drawings for explaining current paths.

As shown in FIG. 5, the chip electronic component EC2 is provided with the element body 3, the first terminal electrode 11, the second terminal electrode 13, the third terminal electrode 15, and the fourth terminal electrode 17 as the chip electronic component EC1 is.

The chip electronic component EC2, as shown in FIG. 6, is provided with first internal conductors 21 and second internal conductors 23 as internal conductors. Each set of first internal conductor 21 and second internal conductor 23 are located in the same layer (or in the same plane).

Each first internal conductor 21 has a conductor portion 21a extending in the long-side direction of the first and second principal faces 3a, 3b, and a conductor portion 21b extending in the short-side direction of the first and second principal faces 3a, 3b. Each second internal conductor 23 has a conductor portion 23a extending in the long-side direction of the first and second principal faces 3a, 3b, and a conductor portion 23b extending in the short-side direction of the first and second principal faces 3a, 3b. The first and second internal conductors 21, 23 are comprised of an electroconductive material (e.g., Ag) which is usually used for internal electrodes of multilayer electric elements, as the internal conductors 7 are. Each of the first and second internal conductors 21, 23 is also composed of a sintered body of an electroconductive paste containing the foregoing electroconductive material.

The conductor portion 21a has its end exposed in the first side face 3c. The conductor portion 21a is physically and electrically connected to the first terminal electrode 11. The end of the conductor portion 21a is widened in order to achieve secure connection to the first terminal electrode 11. The conductor portion 21b has its ends exposed in the third and fourth side faces 3e, 3 f, respectively. The conductor portion 21b is physically and electrically connected to the second and fourth terminal electrodes 13, 17. This configuration results in physically and electrically connecting the first internal conductors 21 to the first terminal electrode 11, the second terminal electrode 13, and the fourth terminal electrode 17.

The conductor portion 23a has its end exposed in the second side face 3d. The conductor portion 23a is physically and electrically connected to the third terminal electrode 15. The end of the conductor portion 23a is widened in order to achieve secure connection to the third terminal electrode 15. The conductor portion 23b has its ends exposed in the third and fourth side faces 3e, 3f, respectively. The conductor portion 23b is physically and electrically connected to the second and fourth terminal electrodes 13, 17. This configuration results in physically and electrically connecting the second internal conductors 23 to the second to fourth terminal electrodes 13-17.

The below will describe current paths in the chip electronic component EC2, with reference to FIGS. 7 and 8.

In the chip electronic component EC2 shown in FIG. 7, for example, the first terminal electrode 11 functions as an input terminal electrode and the second to fourth terminal electrodes 13-17 function as output terminal electrodes. In this case, there are three current paths CP3a-CP3c formed in the chip electronic component EC2. The current path CP3a is a current path through the first and second internal conductors 21, 23 and the second terminal electrode 13 between the first terminal electrode 11 and the third terminal electrode 15. The current path CP3b is a current path through the first internal conductors 21 between the first terminal electrode 11 and the second terminal electrode 13. The current path CP3c is a current path through the first internal conductors 21 between the first terminal electrode 11 and the fourth terminal electrode 17. The current path CP3a is longer by intervention of the second internal conductors 23 and the second terminal electrode 13 than the current paths CP3b, CP3c and thus has the impedance higher than them.

In the chip electronic component EC2 shown in FIG. 8, for example, the second terminal electrode 13 functions as an input terminal electrode and the first terminal electrode 11, the third terminal electrode 15, and the fourth terminal electrode 17 function as output terminal electrodes. In this case, there are three current paths CP4a-CP4c formed in the chip electronic component EC2. The current path CP4a is a current path through the first and second internal conductors 21, 23 (conductor portions 21b, 23b) between the second terminal electrode 13 and the fourth terminal electrode 17. The current path CP4b is a current path through the first internal conductors 21 between the second terminal electrode 13 and the first terminal electrode 11. The current path CP4c is a current path through the second internal conductors 23 between the second terminal electrode 13 and the third terminal electrode 15. The current path CP4a has the path length shorter and the impedance lower than the current paths CP4b, CP4c.

In the present embodiment, as described above, the chip electronic component EC2 also functions as a ferrite chip bead inductor. The current path CP3a has the impedance higher than the current paths CP3b, CP3c. The current path CP4a has the impedance lower than the current paths CP4b, CP4c. The current path CP3a has the impedance higher than the current path CP4a. In this manner, the chip electronic component EC2 has the plurality of current paths with the different impedances (e.g., the current paths CP3a-CP3c, CP4a-CP4c). Accordingly, the chip electronic component EC2 permits easy and wide-range control of impedance, without increase in the number of parts.

In the present embodiment, the chip electronic component is provided with the first internal conductors 21 and the second internal conductors 23 as internal conductors and the first terminal electrode 11 and the third terminal electrode 15 are electrically connected through the first and second internal conductors 21, 23 and the second terminal electrode 13 (the fourth terminal electrode 17). This makes the current path CP3a relatively long between the first terminal electrode 11 and the third terminal electrode 15. Therefore, the chip electronic component EC2 permits wider-range control of impedance.

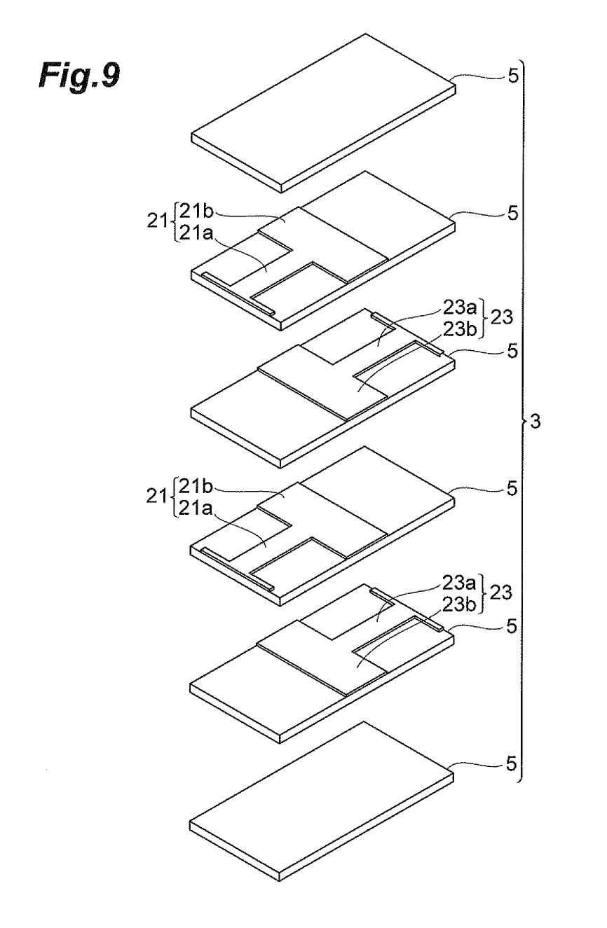

As a modification example of the present embodiment, as shown in FIG. 9, the first internal conductors 21 and the second internal conductors 23 may be located in different layers. FIG. 9 is an exploded perspective view for explaining the modification example.

### Third Embodiment

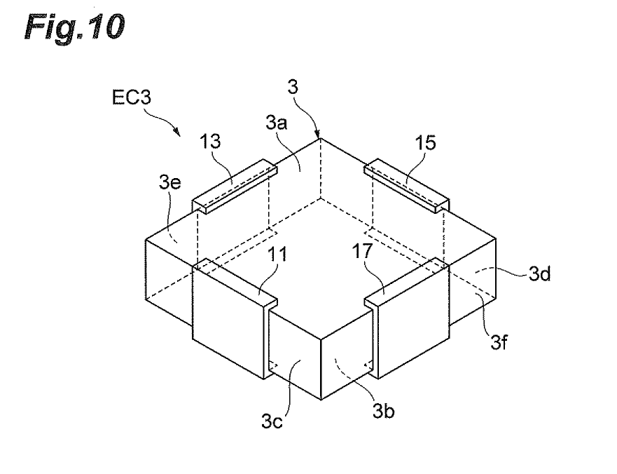

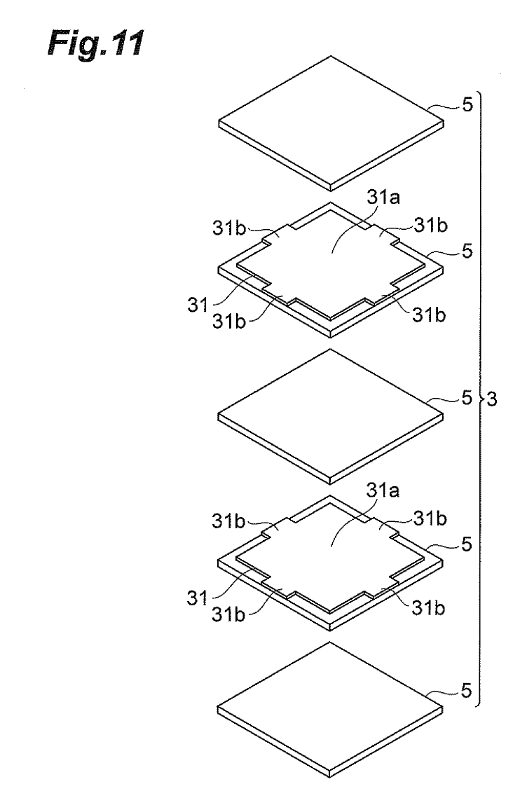

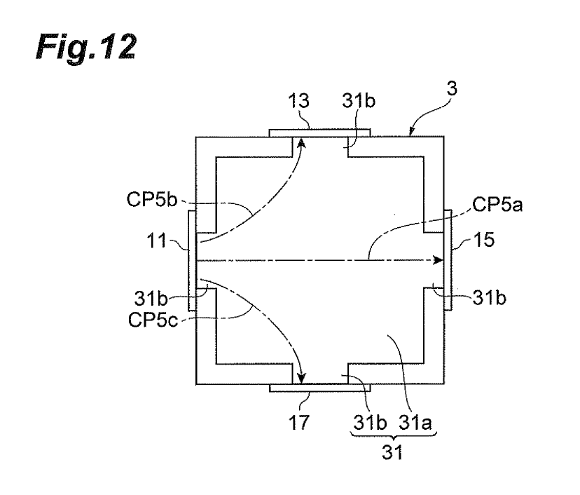

Next, a configuration of a chip electronic component EC3 according to the third embodiment will be described with reference to FIGS. 10 to 12. FIG. 10 is a perspective view showing the chip electronic component according to the third embodiment. FIG. 11 is an exploded perspective view showing configurations of an element body and internal conductors. FIG. 12 is a drawing for explaining current paths.

As shown in FIG. 10, the chip electronic component EC3 is provided with the element body 3, the first terminal electrode 11, the second terminal electrode 13, the third terminal electrode 15, and the fourth terminal electrode 17. In the present embodiment, the first and second principal faces 3a, 3b are of a nearly square shape.

The chip electronic component EC3, as shown in FIG. 11, is provided with internal conductors 31. Each internal conductor 31 has a conductor portion 31a of a nearly square shape, and four conductor portions 31b extending from the conductor portion 31a to the respective side faces 3c-3f. The internal conductors 31 are comprised of an electroconductive material (e.g., Ag) which is usually used for internal electrodes of multilayer electric elements, as the internal conductors 7 are. Each internal conductor 31 is also comprised of a sintered body of an electroconductive paste containing the foregoing electroconductive material.

The ends of the conductor portions 31b are exposed in the respective side faces 3c-3f. The conductor portions 31b are physically and electrically connected to the first to fourth terminal electrodes 11-17. This configuration makes the internal conductors 31 physically and electrically connected to the first to fourth terminal electrodes 11-17.

The below will describe current paths in the chip electronic component EC3, with reference to FIG. 12.

In the chip electronic component EC3 shown in FIG. 12, for example, the first terminal electrode 11 functions as an input terminal electrode and the second to fourth terminal electrodes 13-17 function as output terminal electrodes. In this case, there are three current paths CP5a-CP5c formed in the chip electronic component EC3. The current path CP5a is a current path through the internal conductors 31 between the first terminal electrode 11 and the third terminal electrode 15. The current path CP5b is a current path through the internal conductors 31 between the first terminal electrode 11 and the second terminal electrode 13. The current path CP5c is a current path through the internal conductors 31 between the first terminal electrode 11 and the fourth terminal electrode 17. The current path CP5a is longer than the current paths CP5b, CP5c and thus has the impedance higher than them.

In the present embodiment, as described above, the chip electronic component EC3 also functions as a ferrite chip bead inductor. The current path CP5a has the impedance higher than the current paths CP5b, CP5c. In this manner, the chip electronic component EC3 has the plurality of current paths with the different impedances (e.g., the current paths CP5a-CP5c). Accordingly, the chip electronic component EC3 permits easy and wide-range control of impedance, without increase in the number of parts.

In the present embodiment, the first and second principal faces 3a, 3b of the element body 3 are of the nearly square shape. For this reason, when the chip electronic component EC3 is mounted with the first principal face 3a or the second principal face 3b serving as a mount surface, there is no directionality in mounting of the chip electronic component EC3. Accordingly, the chip electronic component EC3 is improved in workability of mounting.

### Fourth Embodiment

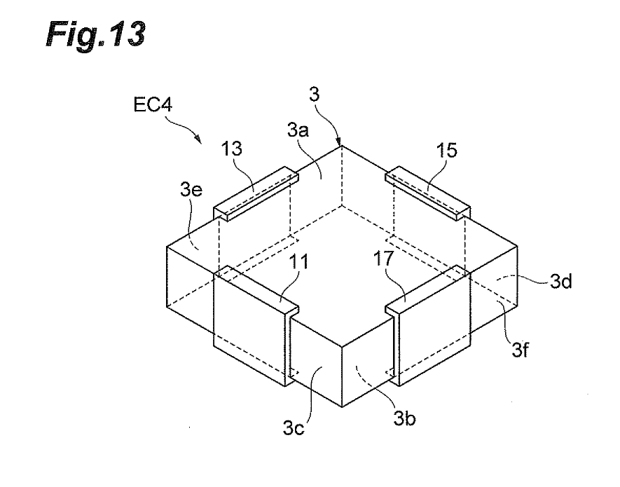

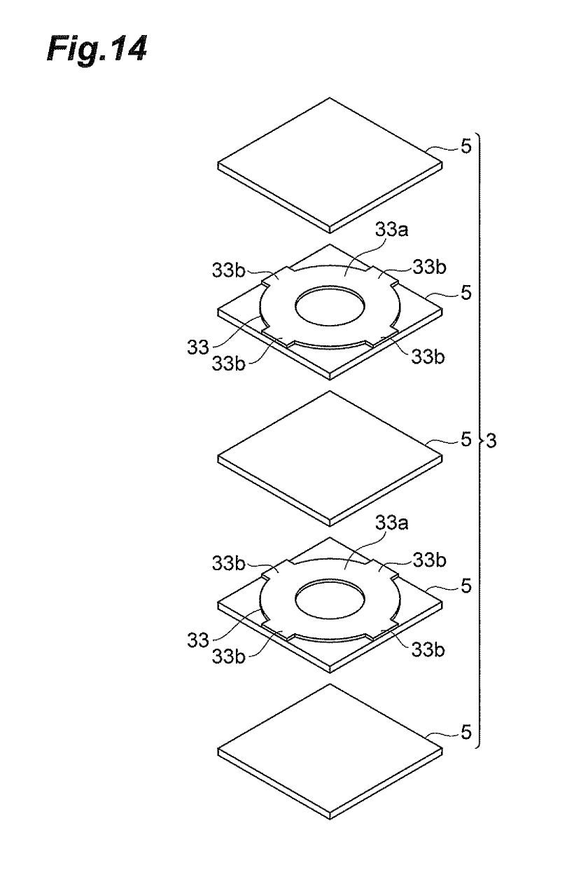

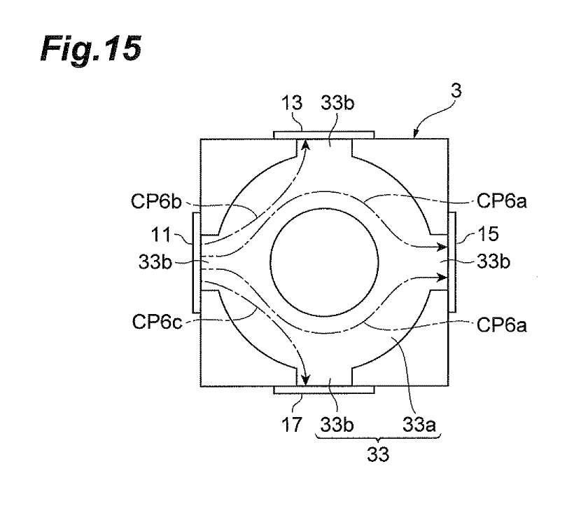

A configuration of a chip electronic component EC4 according to the fourth embodiment will be described below with reference to FIGS. 13 to 15. FIG. 13 is a perspective view showing the chip electronic component according to the fourth embodiment. FIG. 14 is an exploded perspective view showing configurations of an element body and internal conductors. FIG. 15 is a drawing for explaining current paths.

As shown in FIG. 13, the chip electronic component EC4 is provided with the element body 3, the first terminal electrode 11, the second terminal electrode 13, the third terminal electrode 15, and the fourth terminal electrode 17. In the present embodiment, the first and second principal faces 3a, 3b are of a nearly square shape.

The chip electronic component EC4, as shown in FIG. 14, is provided with internal conductors 33. The internal conductors 33 are comprised of an electroconductive material (e.g., Ag) which is usually used for internal electrodes of multilayer electric elements, as the internal conductors 7 and others are. Each of the internal conductors 33 is also composed of a sintered body of an electroconductive paste containing the foregoing electroconductive material.

Each internal conductor 33 has a conductor portion 33a of a ring shape, and four conductor portions 33b extending from the conductor portion 33a to the respective side faces 3c-3f. The ends of the conductor portions 33b are exposed in the respective side faces 3c-3f. The conductor portions 33b are physically and electrically connected to the first to fourth terminal electrodes 11-17. This configuration makes the internal conductors 31 physically and electrically connected to the first to fourth terminal electrodes 11-17.

The below will describe current paths in the chip electronic component EC4, with reference to FIG. 15.

In the chip electronic component EC4 shown in FIG. 15, for example, the first terminal electrode 11 functions as an input terminal electrode and the second to fourth terminal electrodes 13-17 function as output terminal electrodes. In this case, there are three current paths CP6a-CP6c formed in the chip electronic component EC4. The current path CP6a is a current path through the internal conductors 33 between the first terminal electrode 11 and the third terminal electrode 15. The current path CP6b is a current path through the internal conductors 33 between the first terminal electrode 11 and the second terminal electrode 13. The current path CP6c is a current path through the internal conductors 33 between the first terminal electrode 11 and the fourth terminal electrode 17. The current path CP6a is longer than the current paths CP6b, CP6c and has the impedance higher than them.

In the present embodiment, as described above, the chip electronic component EC4 also functions as a ferrite chip bead inductor. The current path CP6a has the impedance higher than the current paths CP6b, CP6c. In this manner, the chip electronic component EC4 has the plurality of current paths with the different impedances (e.g., the current paths CP6a-CP6c). Accordingly, the chip electronic component EC4 permits easy and wide-range control of impedance, without increase in the number of parts.

In the present embodiment, as in the third embodiment, when the chip electronic component EC4 is mounted with the first principal face 3a or the second principal face 3b serving as a mount surface, there is no directionality in mounting of the chip electronic component EC4. Therefore, the chip electronic component EC4 is improved in workability of mounting.

### Fifth Embodiment

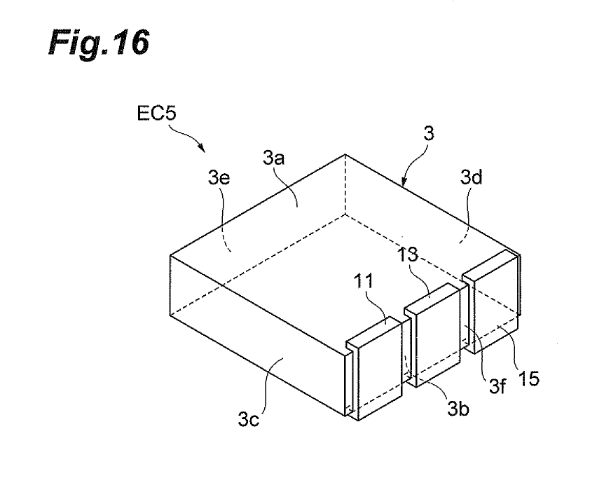

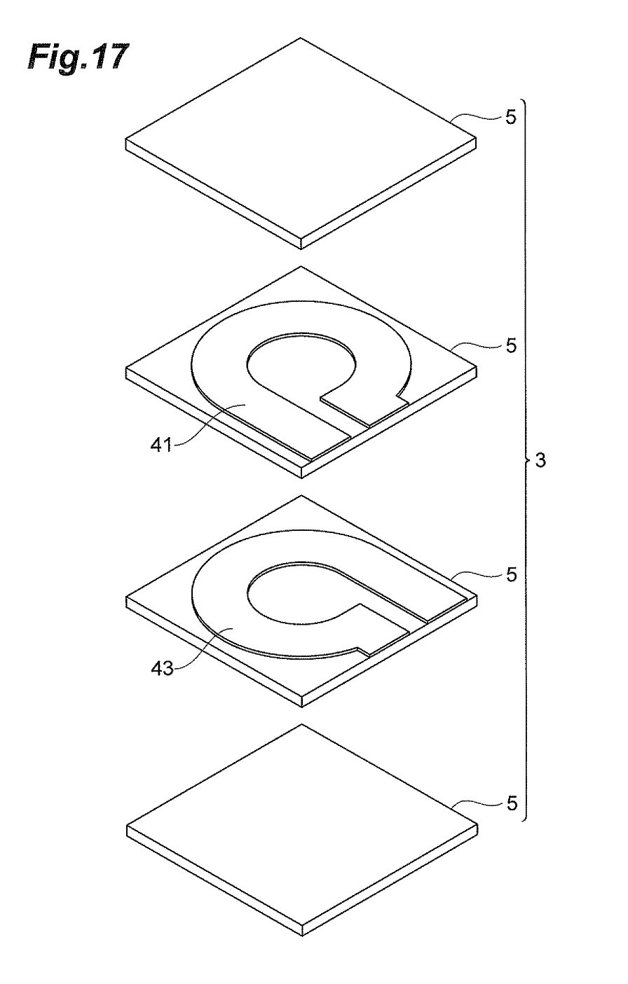

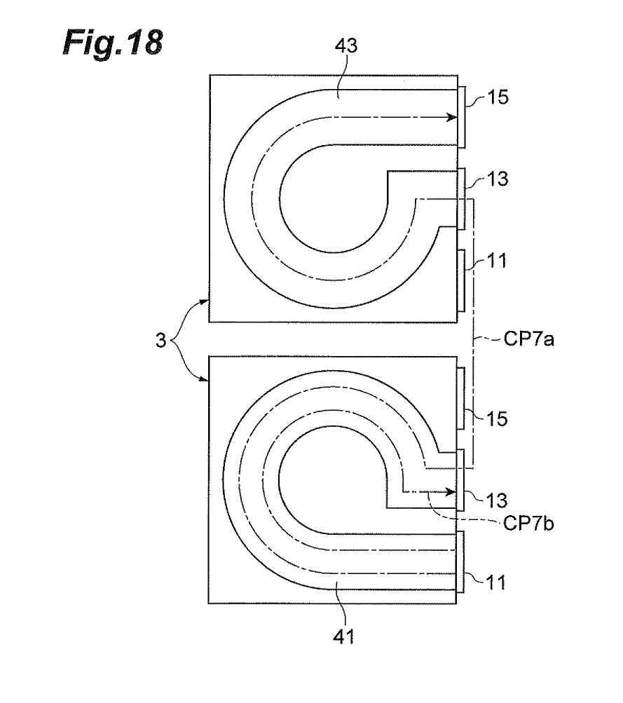

First, a configuration of a chip electronic component EC5 according to the fifth embodiment will be described with reference to FIGS. 16 to 18. FIG. 16 is a perspective view showing the chip electronic component according to the fifth embodiment. FIG. 17 is an exploded perspective view showing configurations of an element body and internal conductors. FIG. 18 is a drawing for explaining current paths.

The chip electronic component EC5, as shown in FIG. 16, is provided with the element body 3, the first terminal electrode 11, the second terminal electrode 13, and the third terminal electrode 15. The first terminal electrode 11, the second terminal electrode 13, and the third terminal electrode 15 are arranged on one side face (e.g., the fourth side face 3f) out of the first to fourth side faces 3c-3f.

The chip electronic component EC5, as shown in FIG. 17, is provided with a first internal conductor 41 and a second internal conductor 43 as internal conductors. The first internal conductor 41 and the second internal conductor 43 are located in different layers. The first and second internal conductors 41, 43 are comprised of an electroconductive material (e.g., Ag) which is usually used for internal electrodes of multilayer electric elements, as the internal conductors 7 and others are. Each of the first and second internal conductors 41, 43 is also composed of a sintered body of an electroconductive paste containing the foregoing electroconductive material.

The first and second internal conductors 41, 43 have their ends exposed in the fourth side face 3f. The first internal conductor 41 is physically and electrically connected to the first terminal electrode 11 and the second terminal electrode 13. The second internal conductor 43 is physically and electrically connected to the second terminal electrode 13 and the third terminal electrode 15.

The below will describe current paths in the chip electronic component EC5, with reference to FIG. 18. In FIG. 18, the internal conductors 41, 43 and the terminal electrodes 11-15 are illustrated in juxtaposition on the drawing, for convenience sake of description.

In the chip electronic component EC5 shown in FIG. 18, for example, the first terminal electrode 11 functions as an input terminal electrode and the second and third terminal electrodes 13, 15 function as output terminal electrodes. In this case, there are two current paths CP7a, CP7b formed in the chip electronic component EC5. The current path CP7a is a current path through the first and second internal conductors 41, 43 and the second terminal electrode 13 between the first terminal electrode 11 and the third terminal electrode 15. The current path CP7b is a current path through the first internal conductor 41 between the first terminal electrode 11 and the second terminal electrode 13. The current path CP7a is longer by intervention of the second internal conductor 43 and the second terminal electrode 13 than the current path CP7b, and thus has the impedance higher than it.

In the present embodiment, as described above, the chip electronic component EC5 also functions as a ferrite chip bead inductor. The current path CP7a has the impedance higher than the current path CP7b. In this manner, the chip electronic component EC5 has the plurality of current paths with the different impedances (e.g., the current paths CP7a, CP7b). Accordingly, the chip electronic component EC5 permits easy and wide-range control of impedance, without increase in the number of parts.

In the present embodiment, the chip electronic component is provided with the first internal conductor 41 and the second internal conductor 43 as internal conductors and the first terminal electrode 11 and the third terminal electrode 15 are electrically connected through the first and second internal conductors 41, 43 and the second terminal electrode 13. This makes the current path CP7a relatively long between the first terminal electrode 11 and the third terminal electrode 15. Accordingly, the chip electronic component EC5 permits wider-range control of impedance.

In the present embodiment, the first terminal electrode 11, the second terminal electrode 13, and the third terminal electrode 15 are arranged on the same face (the fourth side face 3f) of the element body 3. This makes the chip electronic component EC5 improved in workability of mounting. In the chip electronic component EC5, the side face (the fourth side face 3f in the present embodiment) on which the first terminal electrode 11, the second terminal electrode 13, and the third terminal electrode 15 are arranged can also be used as a mount surface, as well as the first and second principal faces 3a, 3b.

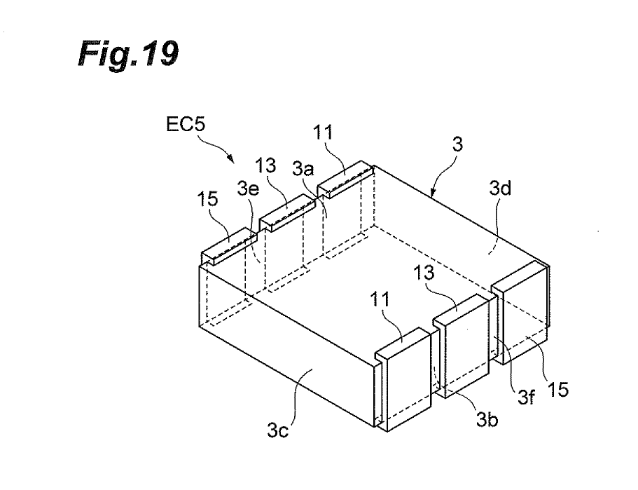

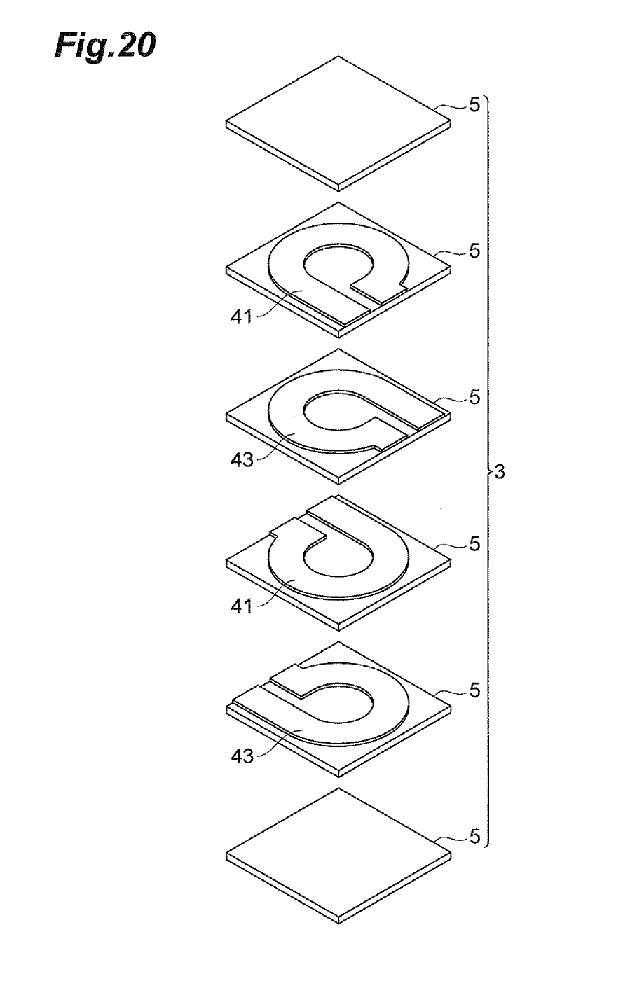

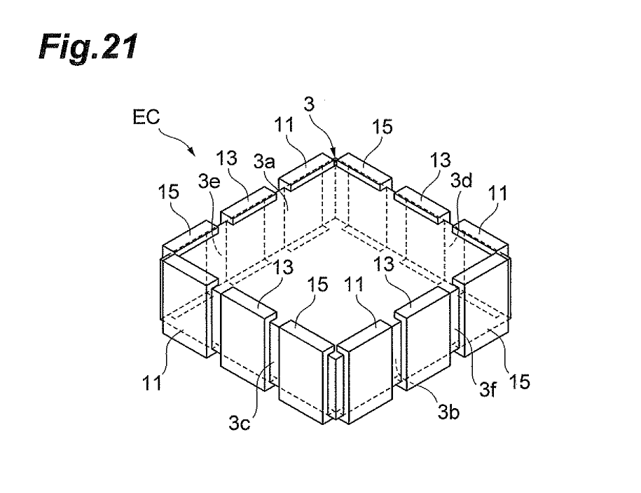

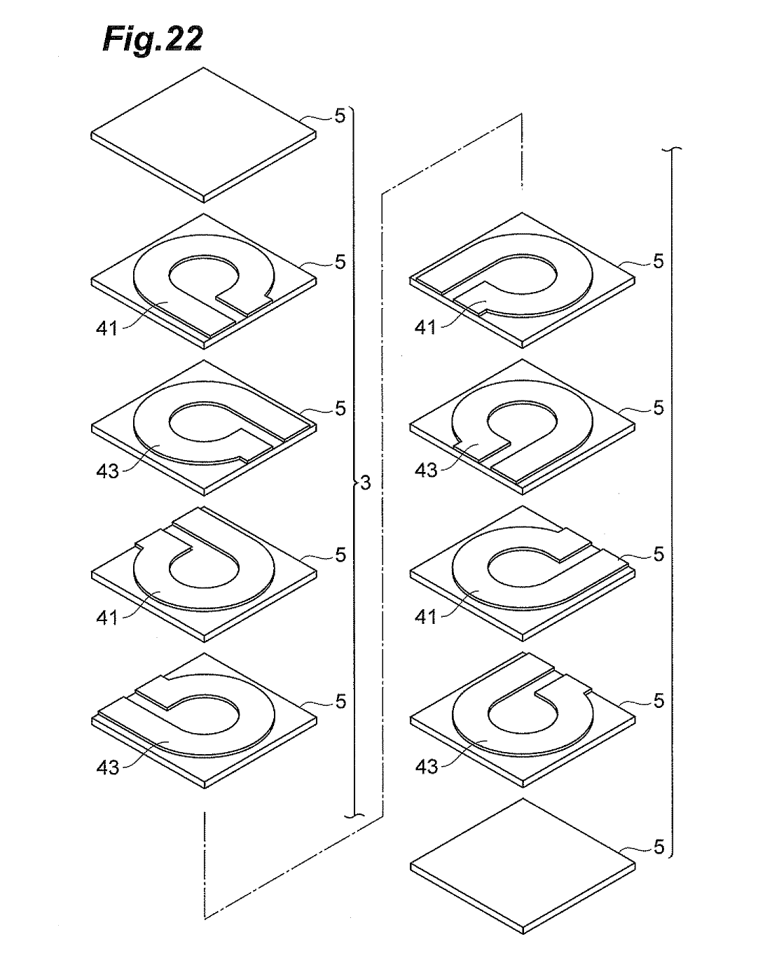

Modification examples of the chip electronic component EC5 will be described below with reference to FIGS. 19 to 22. FIG. 19 is a perspective view showing a modification example of the chip electronic component according to the fifth embodiment. FIG. 20 is an exploded perspective view showing configurations of an element body and internal conductors. FIG. 21 is a perspective view showing another modification example of the chip electronic component according to the fifth embodiment. FIG. 22 is an exploded perspective view showing configurations of an element body and internal conductors.

In the modification example shown in FIG. 19, the first terminal electrode 11, the second terminal electrode 13, and the third terminal electrode 15 are arranged on each of two side faces (e.g., the third side face 3e and the fourth side face 3f) opposed to each other, out of the first to fourth side faces 3c-3f. As shown in FIG. 20, the first and second internal conductors 41, 43 are also connected to the first to third terminal electrodes 11, 13, 15 arranged on the second side face 3d.

In the modification example shown in FIG. 21, the first terminal electrode 11, second terminal electrode 13, and third terminal electrode 15 are arranged on each of the first to fourth side faces 3c-3f. As shown in FIG. 22, the first and second internal conductors 41, 43 are also connected to the first to third terminal electrodes 11, 13, 15 arranged on each side face 3c-3f.

In either of the modification examples, the chip electronic component EC5 functions as a ferrite chip bead inductor. Accordingly, the chip electronic component EC5 permits easy and wide-range control of impedance, without increase in the number of parts.

### Sixth Embodiment

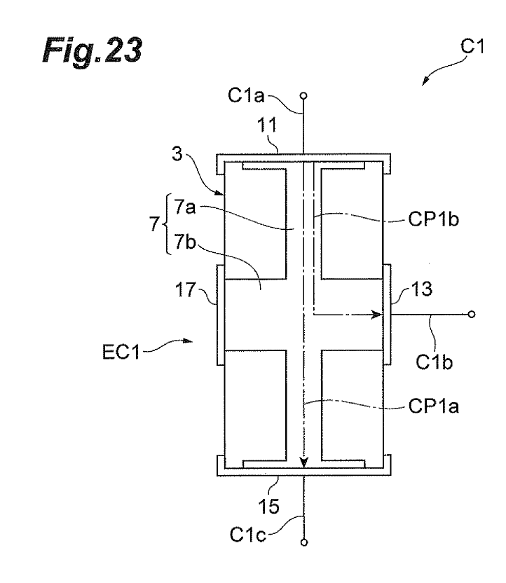

Next, a mounted structure of the chip electronic component EC1 according to the sixth embodiment will be described with reference to FIG. 23. FIG. 23 is a drawing for explaining the mounted structure of the chip electronic component according to the sixth embodiment.

In the present embodiment, the chip electronic component EC1 is inserted in a circuit C1. The circuit C1 is provided with a first line C1a, a second line C1b, and a third line C1c. The first line C1a is physically connected to the first terminal electrode 11 of the chip electronic component EC1. The second line C1b is physically connected to the second terminal electrode 13 of the chip electronic component EC1. The third line C1c is physically connected to the third terminal electrode 15 of the chip electronic component EC1. By these connections, the internal conductors 7 are electrically connected to the first to third lines C1a, C1b, C1c. The connection between each line C1a, C1b, C1c and each terminal electrode 11, 13, 15 is implemented by solder mounting or the like. None of the lines of the circuit C1 is connected to the fourth terminal electrode 17.

Let us suppose in the mounted structure shown in FIG. 23, for example, that an electric current is input through the first line C1a into the chip electronic component EC1 and the electric current is output from the chip electronic component EC1 into the second or third line C1b or C1c. Namely, the first terminal electrode 11 functions as an input terminal electrode and the second and third terminal electrodes 13, 15 function as output terminal electrodes. As described above, the current path CP1a has the higher impedance than the current path CP1b. Therefore, the impedance of the current path between the first line C1a and the third line C1c is higher than the impedance of the current path between the first line C1a and the second line C1b. The impedance of the current path between the first line C1a and the third line C1c is higher than the impedance of the current path between the second line C1b and the third line C1c.

In the present embodiment, as described above, the mounted structure has at least two current paths with the different impedances. Accordingly, the mounted structure permits easy and wide-range control of impedance, without increase in the number of parts.

The present embodiment showed the example in which the chip electronic component EC1 was inserted in the circuit C1, but, instead of the chip electronic component EC1, the chip electronic component EC2, EC3, EC4, or EC5 may be inserted in the circuit C1.

### Seventh Embodiment

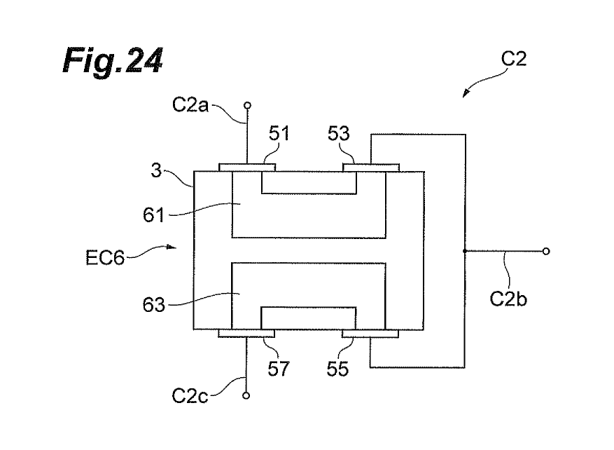

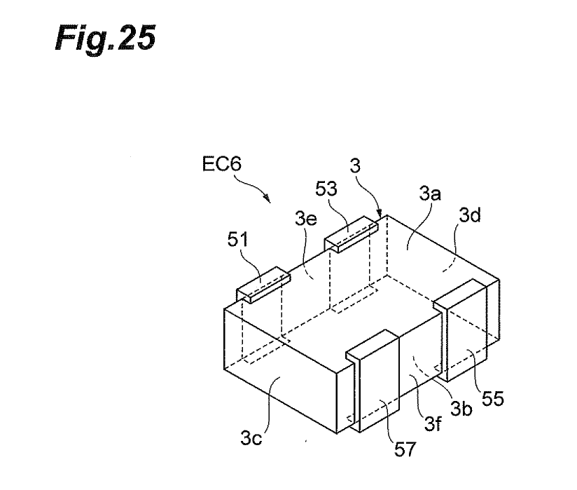

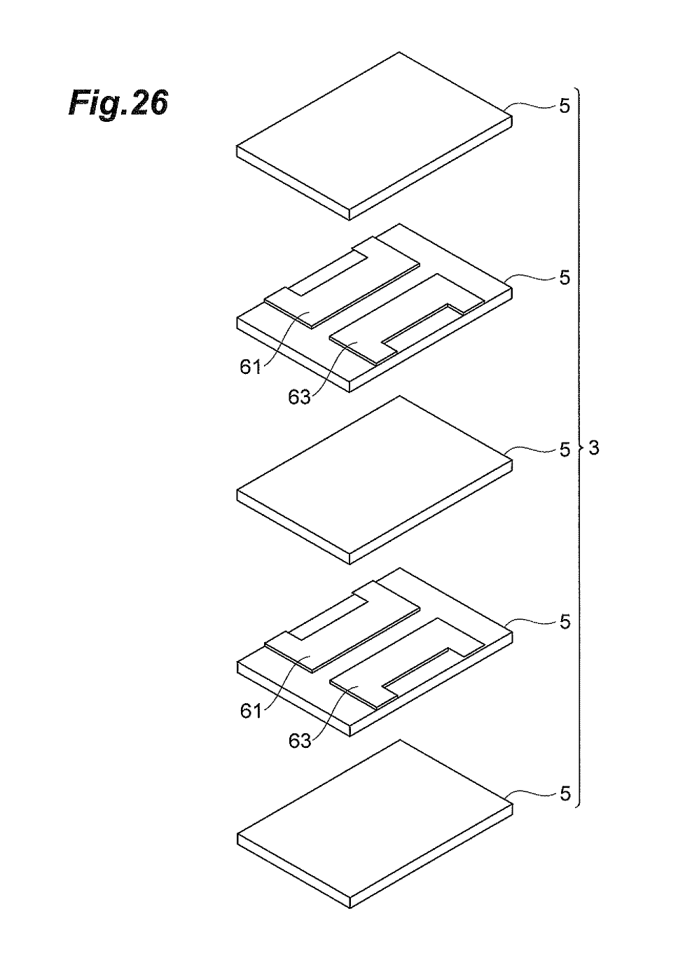

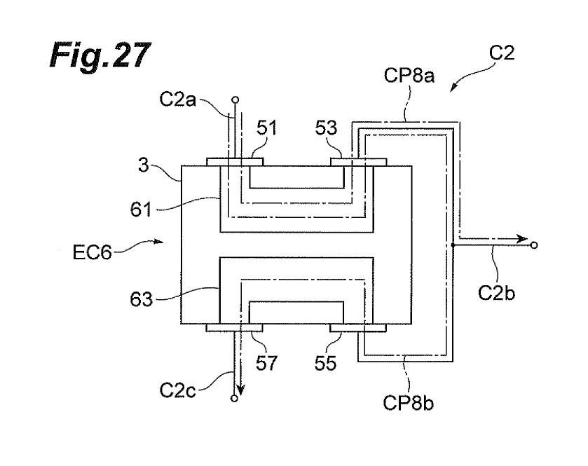

A mounted structure of a chip electronic component EC6 according to the seventh embodiment will be described below with reference to FIGS. 24 to 27. FIG. 24 is a drawing for explaining the mounted structure of the chip electronic component according to the seventh embodiment. FIG. 25 is a perspective view showing the chip electronic component. FIG. 26 is an exploded perspective view showing configurations of an element body and internal conductors. FIG. 27 is a drawing for explaining current paths.

In the present embodiment, the chip electronic component EC6 is inserted in a circuit C2. The circuit C2 is provided with a first line C2a, a second line C2b, and a third line C2c. The chip electronic component EC6, as also shown in FIG. 25, is provided with the element body 3, a first terminal electrode 51, a second terminal electrode 53, a third terminal electrode 55, and a fourth terminal electrode 57.

The first terminal electrode 51 and the second terminal electrode 53 are arranged on the third side face 3e. The first terminal electrode 51 and the second terminal electrode 53 are arranged in juxtaposition along the longitudinal direction of the element body 3. The third terminal electrode 55 and the fourth terminal electrode 57 are arranged on the fourth side face 3f. The third terminal electrode 55 and the fourth terminal electrode 57 are arranged in juxtaposition along the longitudinal direction of the element body 3. The first terminal electrode 51 and the fourth terminal electrode 57 are arranged opposite to each other in the direction in which the third side face 3e and the fourth side face 3f are opposed (or in the transverse direction of the element body 3). The second terminal electrode 53 and the third terminal electrode 55 are arranged opposite to each other in the direction in which the third side face 3e and the fourth side face 3f are opposed.

The first to fourth terminal electrodes 51-57 are formed, for example, by applying an electroconductive paste containing an electroconductive metal powder and a glass frit, onto the exterior surface of the element body 1 and sintering it. A plated layer can be optionally formed on the first to fourth terminal electrodes 51-57 thus formed, as occasion demands.

The chip electronic component EC6, as shown in FIG. 26, is provided with first internal conductors 61 and second internal conductors 63. Each set of first internal conductor 61 and the second internal conductor 63 are located in the same layer (or in the same plane). The two ends of the first internal conductors 61 are exposed in the third side face 3e. The first internal conductors 61 are physically and electrically connected to the first and second terminal electrodes 51, 53. The two ends of the second internal conductors 63 are exposed in the fourth side face 3f. The second internal conductors 63 are physically and electrically connected to the third and fourth terminal electrodes 55, 57. The first and second internal conductors 61, 63 are comprised of an electroconductive material (e.g., Ag) which is usually used for internal electrodes of multilayer electric elements, as the internal conductors 7 and others are. Each of the first and second internal conductors 61, 63 is composed of a sintered body of an electroconductive paste containing the foregoing electroconductive material.

Let us suppose in the mounted structure shown in FIG. 27, for example, that an electric current is input through the first line C2a into the chip electronic component EC6 and the electric current is output from the chip electronic component EC6 into the second or third line C2b, C2c. Namely, the first terminal electrode 51 functions as an input terminal electrode and the second and fourth terminal electrodes 53, 57 function as output terminal electrodes. In this case, two current paths CP8a, CP8b are formed in the mounted structure.

The current path CP8a is a current path through the first terminal electrode 51, the first internal conductors 61, and the second terminal electrode 53 between the first line C2a and the second line C2b. The current path CP8b is a current path through the first terminal electrode 51, the first internal conductors 61, the second terminal electrode 53, the third terminal electrode 55, the second internal conductors 63, and the fourth terminal electrode 57 between the first line C2a and the third line C2c. Since the second terminal electrode 53 and the third terminal electrode 55 are connected to the second line C2b, the current path CP8b is formed. The current path CP8b is longer than the current path CP8a and has the impedance higher than it. The current path through the fourth terminal electrode 57, the second internal conductors 63, and the third terminal electrode 55 between the third line C2c and the second line C2b is shorter than the current path CP8b and has the impedance lower than it.

In the present embodiment, as described above, the mounted structure has at least two current paths with the different impedances. Accordingly, the mounted structure permits easy and wide-range control of impedance, without increase in the number of parts.

In the chip electronic component EC6, the first terminal electrode 51 and the fourth terminal electrode 57 are electrically connected through the first internal conductors 61, the second terminal electrode 53, the second line C2b, the third terminal electrode 55, and the second internal conductors 63. Since the current path between the first terminal electrode 51 and the fourth terminal electrode 57 is relatively long, control of impedance can be performed over a wider range.

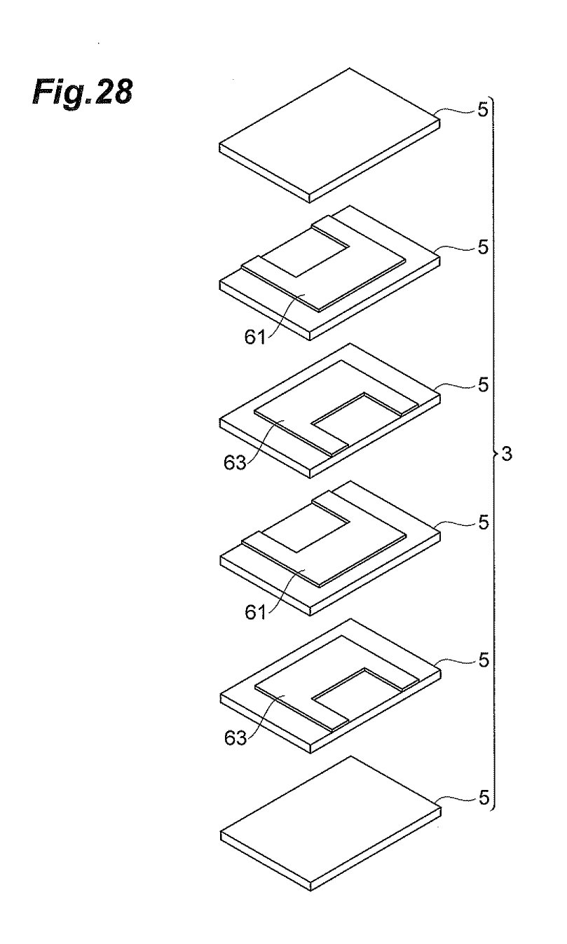

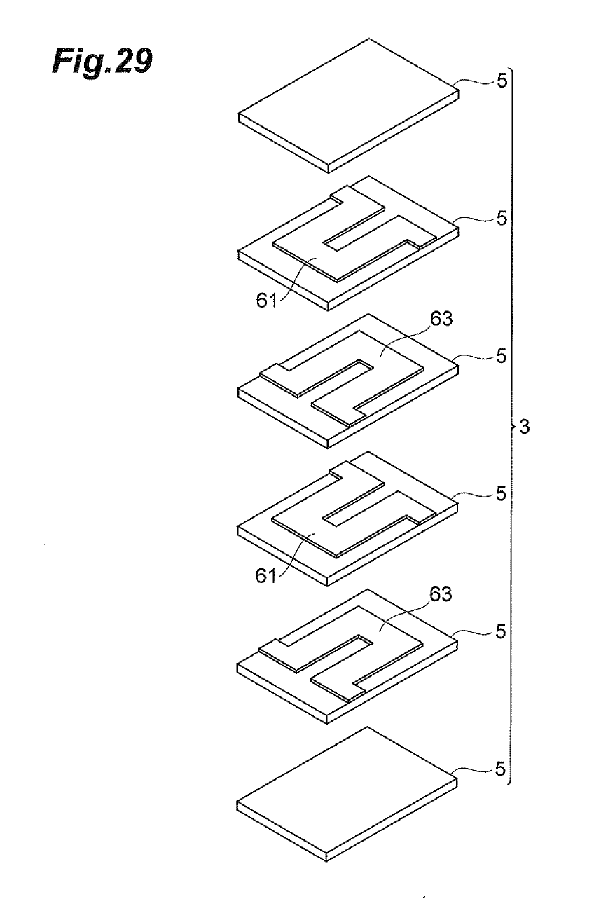

As modification examples of the chip electronic component EC6, the first internal conductors 61 and the second internal conductors 63 may be located in different layers, as shown in FIGS. 28 to 30. FIGS. 28 to 30 are exploded perspective views for explaining the modification examples of the chip electronic component.

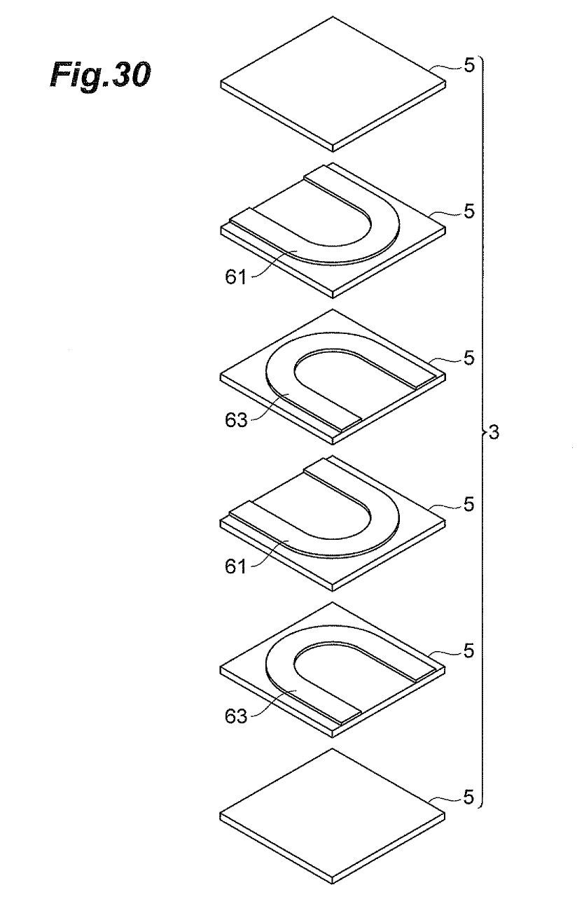

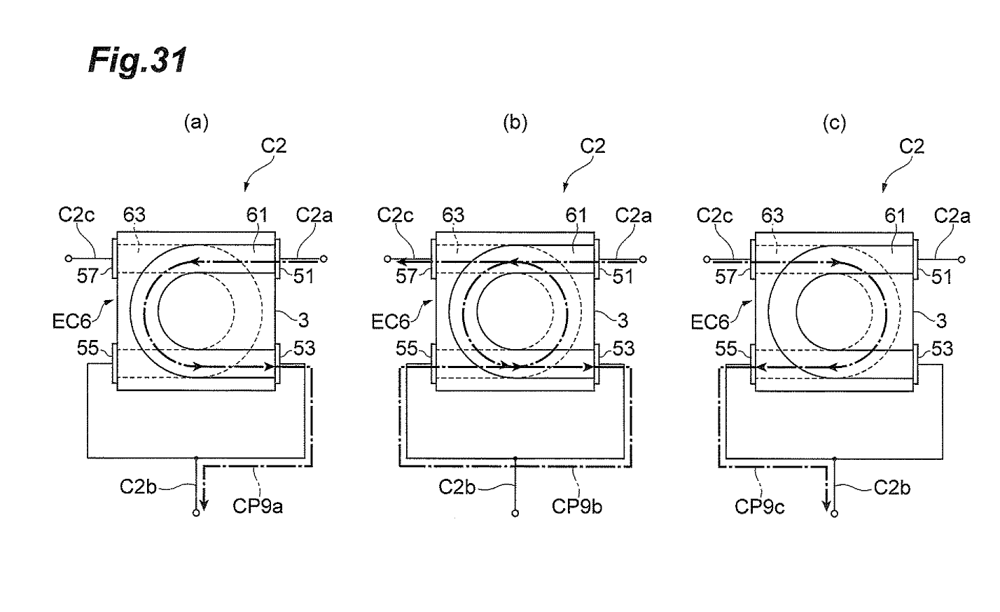

For example, current paths formed in the case where the chip electronic component EC6 according to the modification example shown in FIG. 30 is inserted in the circuit C2 will be described with reference to FIG. 31. FIG. 31 is a drawing for explaining the current paths in the modification example of the mounted structure of the chip electronic component according to the seventh embodiment. In FIG. 31, the first internal conductors 61 and the second internal conductors 63 are illustrated in juxtaposition on the drawing, for convenience sake of description.

In the present modification example, three current paths CP9a, CP9b, CP9c are formed as shown in (a) to (c) of FIG. 31. The current path CP9a is a current path through the first terminal electrode 51, the first internal conductors 61, and the second terminal electrode 53 between the first line C2a and the second line C2b. The current path CP9b is a current path through the first terminal electrode 51, the first internal conductors 61, the second terminal electrode 53, the third terminal electrode 55, the second internal conductors 63, and the fourth terminal electrode 57 between the first line C2a and the third line C2c. The current path CP9c is a current path through the fourth terminal electrode 57, the second internal conductors 63, and the third terminal electrode 55 between the third line C2c and the second line C2b. The current path CP9b is longer than the current paths CP9a, CP9c and has the impedance higher than them.

In the present modification example, as described above, the mounted structure also has at least two current paths with the different impedances. Accordingly, the mounted structure permits easy and wide-range control of impedance, without increase in the number of parts.

### Eighth Embodiment

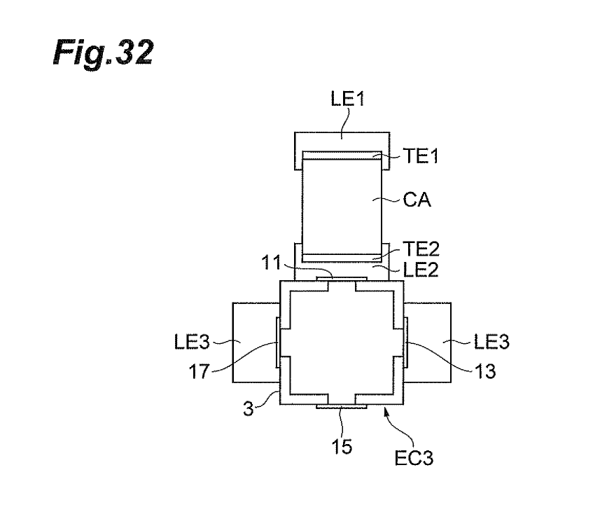

A mounted structure of the chip electronic component EC3 according to the eighth embodiment will be described below with reference to FIG. 32. FIG. 32 is a drawing for explaining the mounted structure of the chip electronic component according to the eighth embodiment.

In the present embodiment, the chip electronic component EC3 and a capacitor CA are connected in series. The chip electronic component EC3 and the capacitor CA are inserted, for example, between power lines to an IC (Integrated Circuit) chip.

The capacitor CA is a so-called multilayer chip capacitor and is provided with a pair of terminal electrodes TE1, TE2. The terminal electrode TE1 is physically and electrically connected to a land electrode LE1. The terminal electrode TE2 is physically and electrically connected to a land electrode LE2. The connection between each terminal electrode TE1, TE2 and each land electrode LE1, LE2 is implemented, for example, by solder mounting.

The first terminal electrode 11 of the chip electronic component EC3 is physically and electrically connected to the land electrode LE2. By this connection, the chip electronic component EC3 and the capacitor CA are connected in series so that the first terminal electrode 11 is located on the capacitor CA side. Each of the second and fourth terminal electrodes 13, 17 of the chip electronic component EC3 is physically and electrically connected to a land electrode LE3. In this case, the first terminal electrode 11 functions as an input terminal electrode and the second and fourth terminal electrodes 13, 17 function as output terminal electrodes. The connection between each terminal electrode 11, 13, 17 and each land electrode LE2, LE3 is implemented, for example, by solder mounting.

In the present embodiment, the chip electronic component EC3 is mounted as described above. The chip electronic component EC3 has at least two current paths with the different impedances, as described above. Accordingly, the mounted structure permits easy and wide-range control of impedance, without increase in the number of parts.

In the mounted structure of the present embodiment, the chip electronic component EC3 functioning as a ferrite chip bead inductor, and the capacitor CA are connected in series. For this reason, a resistive component of the ferrite chip bead inductor (chip electronic component EC3) acts as an equivalent series resistance of the capacitor CA. The resistive component of the ferrite chip bead inductor is composed of the sum of a DC resistive component and a loss which increases in a high frequency band.

In the mounted structure of the present embodiment, therefore, the impedance increases in the high frequency band and therefore high-frequency noise can be suitably removed. The ferrite chip bead inductor functions as an inductor component rather than the resistive component in a low frequency band. For this reason, the impedance can be kept low in the low frequency band in the mounted structure. Since the capacitor CA is mounted, low-frequency noise is absorbed by the capacitor CA. As a consequence, the mounted structure can suitably remove the low-frequency noise.

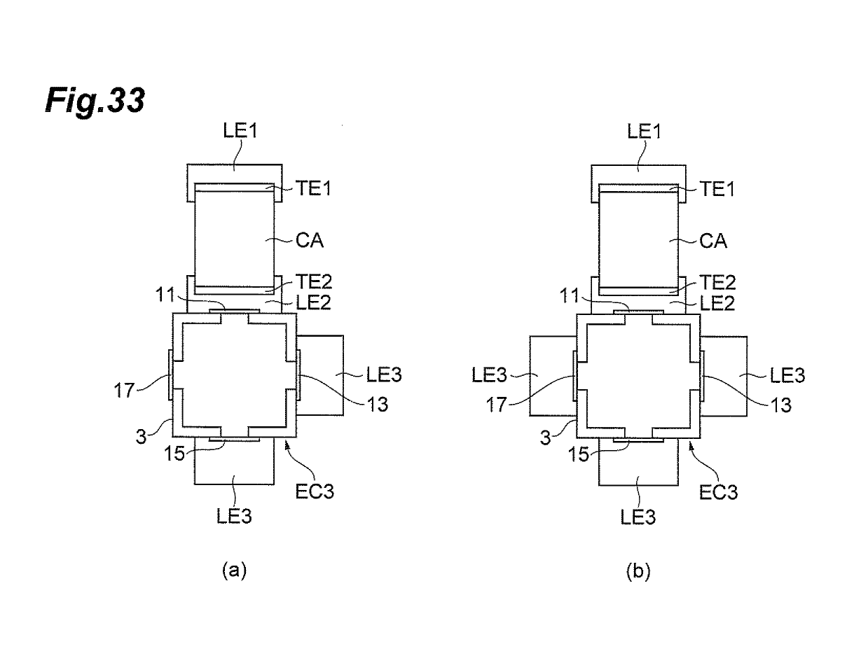

In the present embodiment, the second and fourth terminal electrodes 13, 17 function as output terminal electrodes, but the second and third terminal electrodes 13, 15 may be configured to function as output terminal electrodes as shown in FIG. 33. Furthermore, the second to fourth terminal electrodes 13-17 may be configured to function as output terminal electrodes. FIG. 33 is a drawing for explaining modification examples of the mounted structure of the chip electronic component according to the eighth embodiment.

In the chip electronic component EC3, as described based on FIG. 12, the current path CP5a has the higher impedance than the current paths CP5b, CP5c. Therefore, the mounted structure shown in (a) of FIG. 33 has the higher impedance than the mounted structure shown in FIG. 32. Since the mounted structure shown in (b) of FIG. 33 has more current paths than the mounted structure shown in FIG. 32, it has the lower impedance.

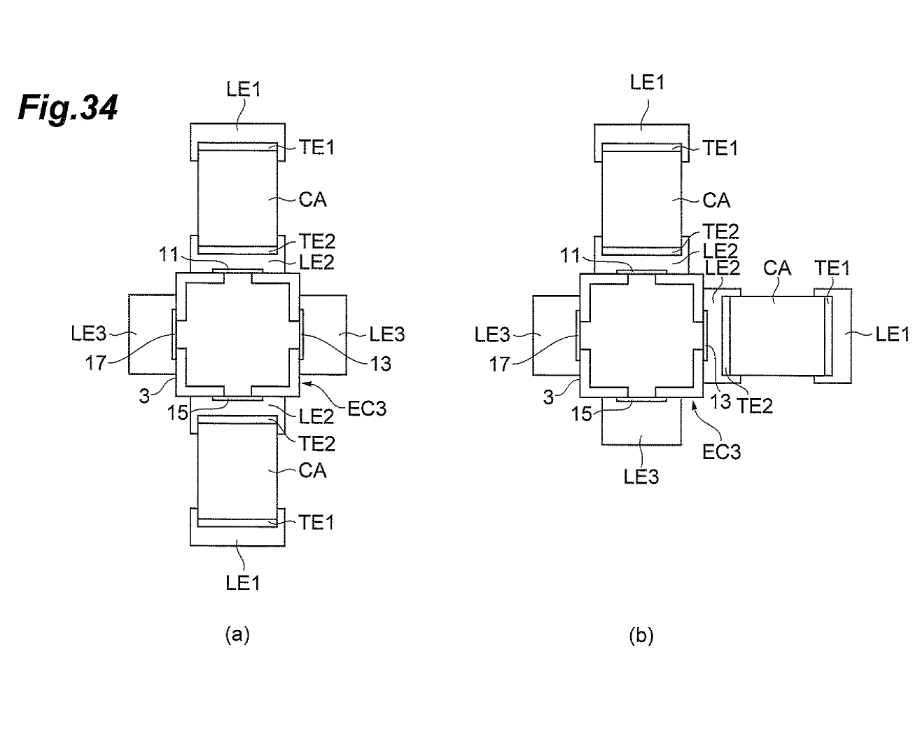

The present embodiment showed the example in which the number of capacitor CA was one, but the number of capacitor CA may be two or more (e.g., two) as shown in FIG. 34. FIG. 34 is a drawing for explaining modification examples of the mounted structure of the chip electronic component according the eighth embodiment.

In the mounted structure shown in (a) of FIG. 34, the capacitors CA are connected respectively to the first terminal electrode 11 and to the third terminal electrode 15. In the mounted structure shown in (b) of FIG. 34, the capacitors CA are connected respectively to the first terminal electrode 11 and to the second terminal electrode 13.

### Ninth Embodiment

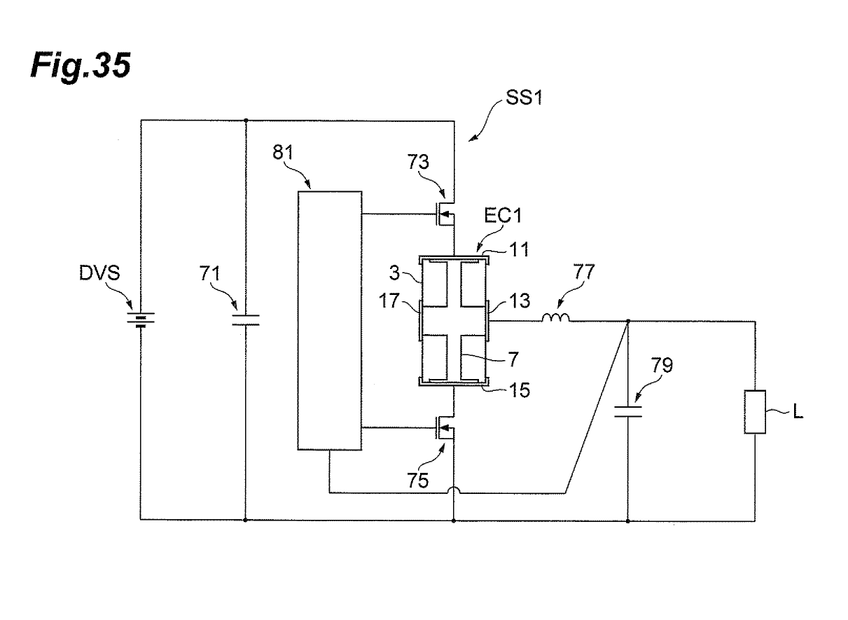

A switching supply circuit SS1 according to the ninth embodiment will be described below with reference to FIG. 35. FIG. 35 is a drawing showing a configuration of the switching supply circuit according to the ninth embodiment. The switching supply circuit SS1 is provided with a first capacitor 71, a first transistor 73, a second transistor 75, an inductor 77, and a second capacitor 79. The switching supply circuit SS1 is further provided with the chip electronic component EC1. The switching supply circuit SS1 is a step-down type switching supply circuit.

The first transistor 73 is connected to a positive electrode of a DC voltage source DVS. The second transistor 75 is connected between a negative electrode of the DC voltage source DVS and the first transistor 73. The first capacitor 71 is connected in parallel to the DC voltage source DVS. The chip electronic component EC1 is inserted at a midpoint between the first transistor 73 and the second transistor 75. The inductor 77 is connected at its one end to the chip electronic component EC1. One end of the second capacitor 79 is connected to the other end of the inductor 77. The other end of the second capacitor 79 is connected to the negative electrode of the DC voltage source DVS. A load L is connected in parallel to the second capacitor 79 in the switching supply circuit SS1.

The first transistor 73 and the second transistor 75 are controlled each by a control signal (gate signal) from a control circuit 81. The control circuit 81 performs PWM (Pulse Width Modulation) control of the first and second transistors 73, 75 so that the output voltage becomes a desired value. The control signals from the control circuit 81 are input to respective gate terminals of the first and second transistors 73, 75.

The first terminal electrode 11 of the chip electronic component EC1 is connected to a source terminal of the first transistor 73. The third terminal electrode 15 of the chip electronic component EC1 is connected to a drain terminal of the second transistor 75. The second terminal electrode 13 of the chip electronic component EC1 is connected to one end of the inductor 77. In the chip electronic component EC1, as described above, the impedance of the current path through the internal conductors 7 between the first terminal electrode 11 and the third terminal electrode 15 is higher than the impedance of the current path through the internal conductors 7 between the first terminal electrode 11 and the second terminal electrode 13.

In the switching supply circuit SS1, the first and second transistors 73, 75 are made alternately conductive by the respective control signals from the control circuit 81. This causes an almost DC voltage to be generated in the second capacitor 79, whereby DC power is supplied to the load L.

In the present embodiment, as described above, the switching supply circuit SS1 is provided with the chip electronic component EC1. The chip electronic component EC1 has at least two current paths with the different impedances, as described above. For this reason, control of impedance is performed readily and over a wide range in the switching supply circuit SS1, without increase in the number of parts.

In the switching supply circuit SS1, the first capacitor 71 is connected in parallel to the DC voltage source DVS and, for this reason, resonance could occur in a loop consisting of the first capacitor 71, the first transistor 73, and the second transistor 75. This resonance phenomenon induces an overshoot or an undershoot in the output from each transistor 73, 75. The overshoot or the undershoot in the output can be a cause of electromagnetic noise.

In the present embodiment, the chip electronic component EC1 is inserted at the midpoint between the first transistor 73 and the second transistor 75. The impedance of the current path through the internal conductors 7 between the first terminal electrode 11 and the third terminal electrode 15 is higher than the impedance of the current path through the internal conductors 7 between the first terminal electrode 11 and the second terminal electrode 13. For this reason, the current path consisting of the first terminal electrode 11, the internal conductors 7, and the third terminal electrode 15 is inserted in the loop consisting of the first capacitor 71, the first transistor 73, and the second transistor 75. Therefore, the loop consisting of the first capacitor 71, the first transistor 73, and the second transistor 75 has the impedance high enough to suppress occurrence of resonance in the loop. As a consequence, the switching supply circuit SS1 can suppress occurrence of electromagnetic noise.

Since the chip electronic component EC1 is inserted at the midpoint between the first transistor 73 and the second transistor 75, the current path consisting of the first terminal electrode 11, the internal conductors 7, and the second terminal electrode 13 is inserted in the power supply line to the load L. The current path consisting of the first terminal electrode 11, internal conductors 7, and second terminal electrode 13 has the impedance lower than the current path consisting of the first terminal electrode 11, internal conductors 7, and third terminal electrode 15. For this reason, it is feasible to suppress consumption of power in the current path consisting of the first terminal electrode 11, internal conductors 7, and second terminal electrode 13.

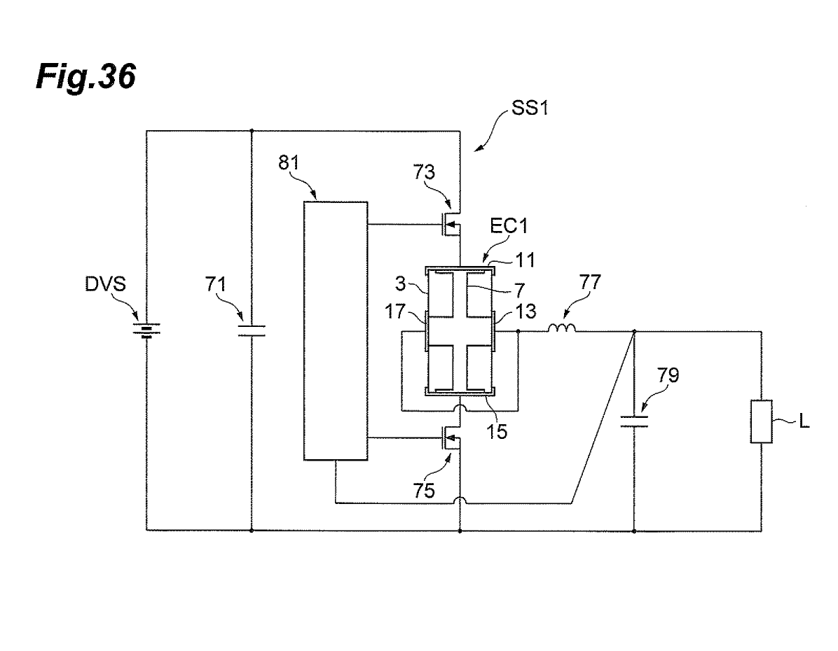

Modification examples of the switching supply circuit SS1 according to the ninth embodiment will be described below with reference to FIGS. 36 to 38. FIGS. 36 to 38 are drawings showing configurations of the modification examples of the switching supply circuit according to the ninth embodiment.

In the modification example of the switching supply circuit SS1 shown in FIG. 36, the fourth terminal electrode 17 of the chip electronic component EC1 is connected to one end of the inductor 77. By this connection, the current path consisting of the first terminal electrode 11, internal conductors 7, and fourth terminal electrode 17 is inserted in the power supply line to the load L. The current path consisting of the first terminal electrode 11, internal conductors 7, and fourth terminal electrode 17 has the lower impedance than the current path consisting of the first terminal electrode 11, internal conductors 7, and third terminal electrode 15.

In the present modification example, as compared to the switching supply circuit SS1 shown in FIG. 35, the number of current paths from the chip electronic component EC1 to the inductor 77 is increased, so as to further decrease the impedance. Therefore, it is feasible to further suppress consumption of power due to the insertion of the switching supply circuit SS1.

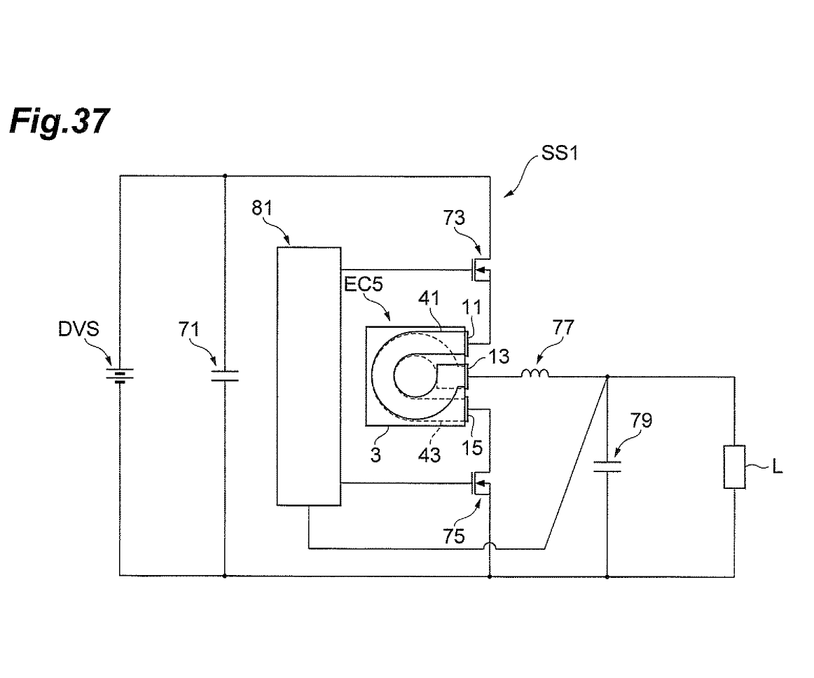

In the modification example of the switching supply circuit SS1 shown in FIG. 37, the chip electronic component EC5 is inserted, instead of the chip electronic component EC1, at the midpoint between the first transistor 73 and the second transistor 75. The chip electronic component EC5 has at least two current paths with the different impedances as the chip electronic component EC1 does. Therefore, control of impedance is also performed readily and over a wide range in the present modification example, without increase in the number of parts, as in the case of the switching supply circuit SS1 shown in FIG. 35.

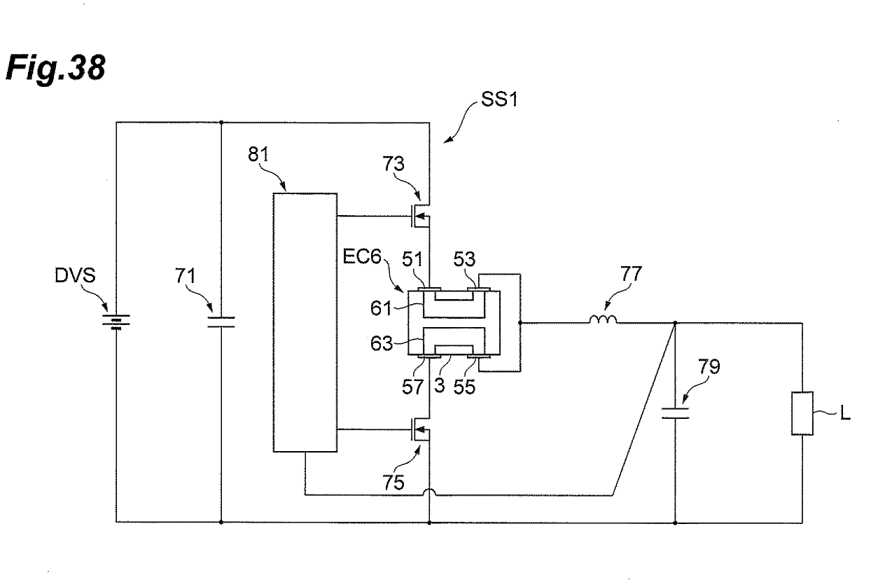

In the modification example of the switching supply circuit SS1 shown in FIG. 38, the chip electronic component EC6 is inserted, instead of the chip electronic component EC1, at the midpoint between the first transistor 73 and the second transistor 75. The first terminal electrode 51 of the chip electronic component EC6 is connected to the source terminal of the first transistor 73. The fourth terminal electrode 57 of the chip electronic component EC6 is connected to the drain terminal of the second transistor 75. The second and third terminal electrodes 53, 55 of the chip electronic component EC1 are connected to one end of the inductor 77.

The current path through the first internal conductors 61, the second terminal electrode 53, the third terminal electrode 55, and the second internal conductors 63 between the first terminal electrode 51 and the fourth terminal electrode 57 has the longer path length and the higher impedance than the current path through the first internal conductors 61 between the first terminal electrode 51 and the second terminal electrode 53. Accordingly, control of impedance is also performed readily and over a wide range in the present modification example, without increase in the number of parts, as in the case of the switching supply circuit SS1 shown in FIG. 35.

### Tenth Embodiment

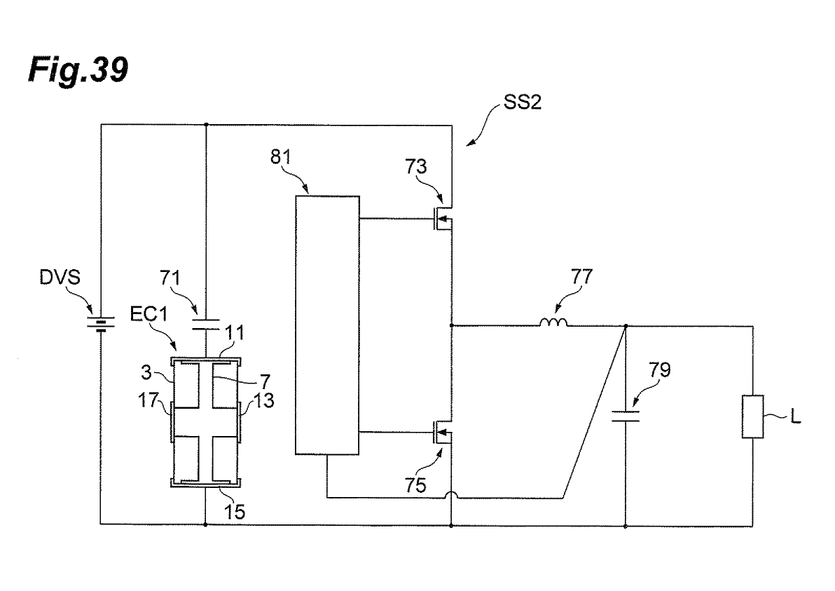

Switching supply circuits SS2 according to the tenth embodiment will be described below with reference to FIGS. 39 to 41. FIGS. 39 to 41 are drawings showing configurations of the switching supply circuits according to the tenth embodiment.

Each switching supply circuit SS2 is provided with the first capacitor 71, first transistor 73, second transistor 75, inductor 77, second capacitor 79, and chip electronic component EC1 as the switching supply circuit SS1 is. The switching supply circuit SS2 is also a step-down type switching supply circuit.

In the switching supply circuit SS2, the chip electronic component EC1 is connected in series to the first capacitor 71. The first terminal electrode 11 of the chip electronic component EC1 is connected to the first capacitor 71. The third terminal electrode 15 of the chip electronic component EC1 is connected to the negative electrode of the DC voltage source DVS.

In the present embodiment, the current path consisting of the first terminal electrode 11, internal conductors 7, and third terminal electrode 15 is inserted in the loop consisting of the first capacitor 71, first transistor 73, and second transistor 75. For this reason, the loop consisting of the first capacitor 71, first transistor 73, and second transistor 75 has the impedance high enough to suppress occurrence of resonance in the loop. As a consequence, the switching supply circuit SS2 can also suppress occurrence of electromagnetic noise.

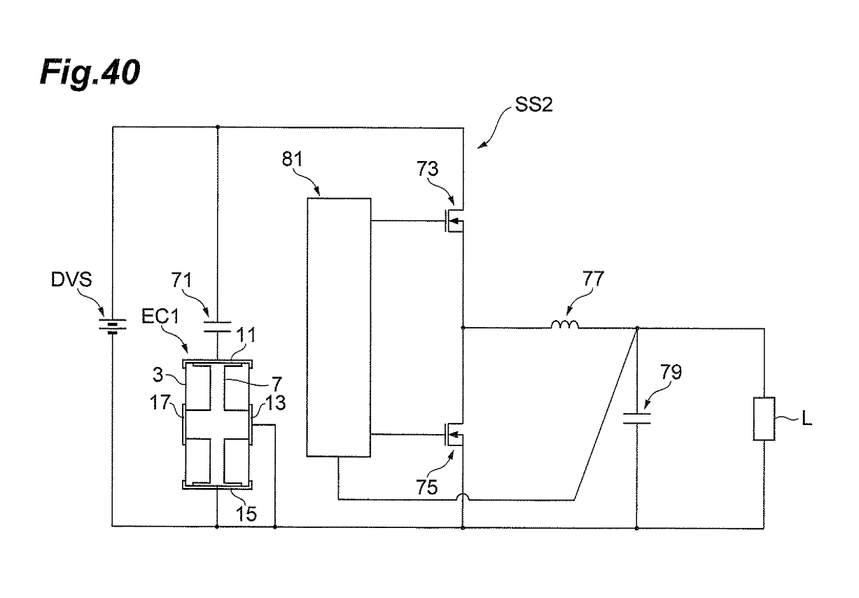

In order to adjust the impedance of the loop consisting of the first capacitor 71, first transistor 73, and second transistor 75, as shown in FIG. 40, the second terminal electrode 13 of the chip electronic component EC1 may be connected to the negative electrode of the DC voltage source DVS. In this case, the number of current paths from the chip electronic component EC1 is increase and, for this reason, the impedance of the loop consisting of the first capacitor 71, first transistor 73, and second transistor 75 is lower in the switching supply circuit SS2 shown in FIG. 40 than in the switching supply circuit SS2 shown in FIG. 39.

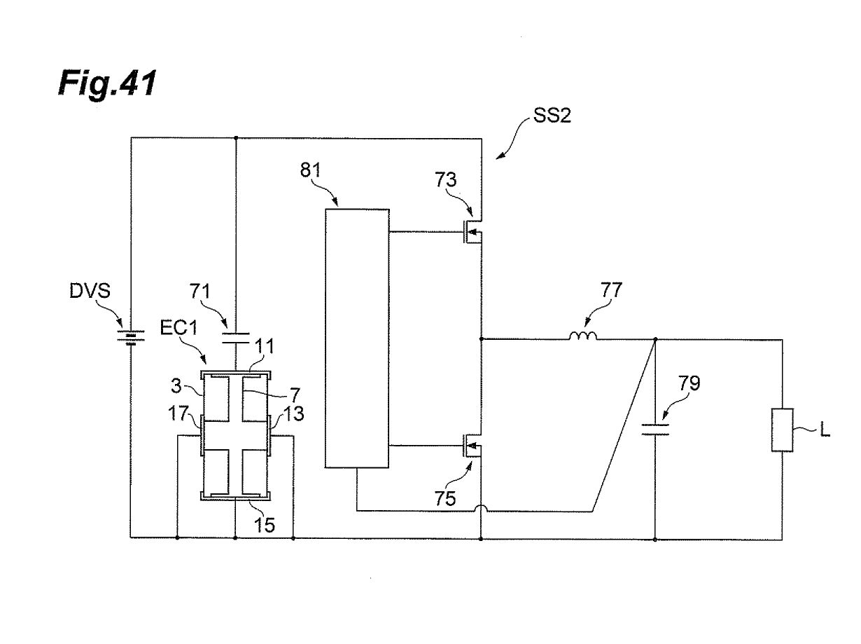

As shown in FIG. 41, the fourth terminal electrode 17 of the chip electronic component EC1 may be connected to the negative electrode of the DC voltage source DVS. In this case, the impedance of the loop consisting of the first capacitor 71, first transistor 73, and second transistor 75 becomes much lower.

In the present embodiment, as described above, the switching supply circuit SS2 is provided with the chip electronic component EC1. The chip electronic component EC1 has at least two current paths with the different impedances, as described above. For this reason, control of impedance is performed readily and over a wide range in the switching supply circuits SS2, without increase in the number of parts.

### Eleventh Embodiment

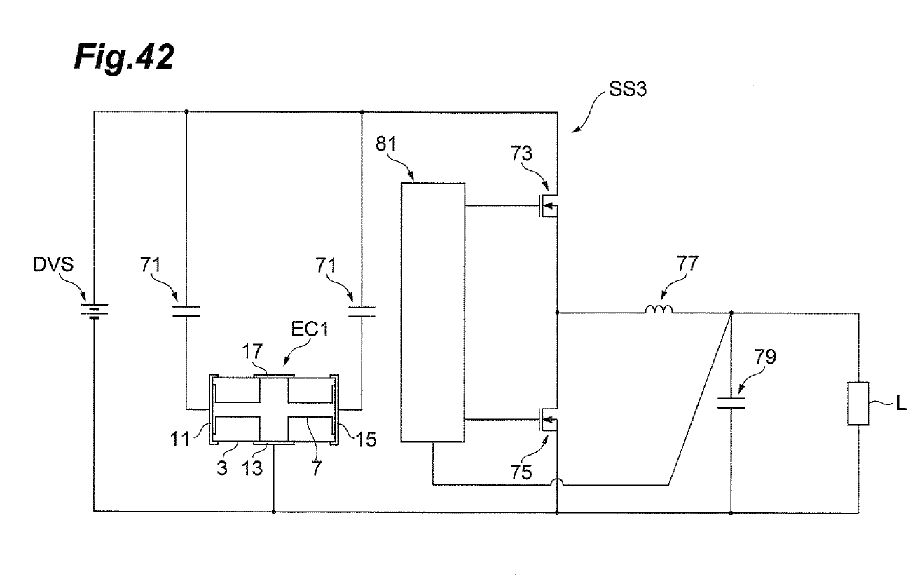

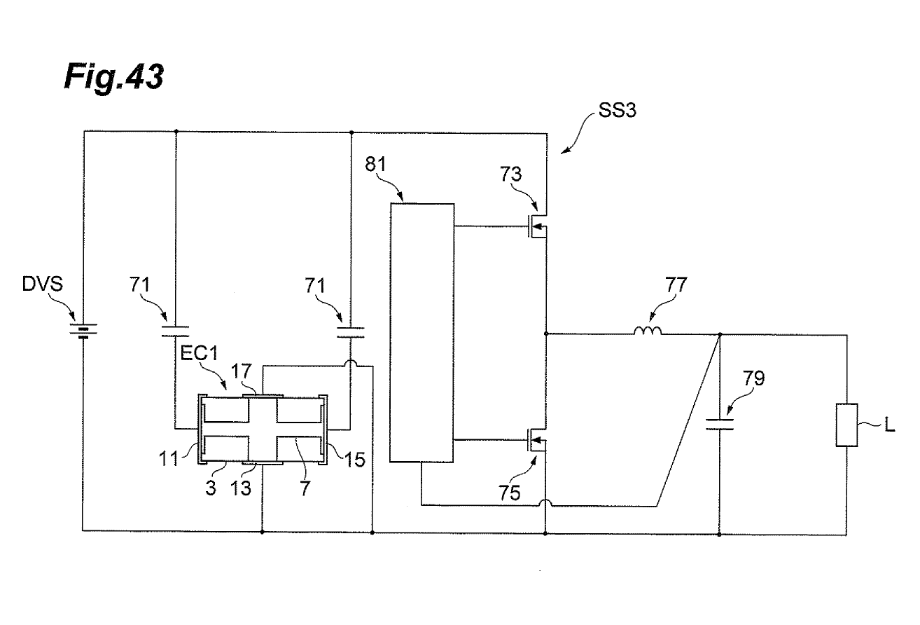

Switching supply circuits SS3 according to the eleventh embodiment will be described below with reference to FIGS. 42 and 43. FIGS. 42 and 43 are drawings showing configurations of the switching supply circuits according to the eleventh embodiment. Each switching supply circuit SS3 is provided with two first capacitors 71, the first transistor 73, the second transistor 75, the inductor 77, the second capacitor 79, and the chip electronic component EC1. The two first capacitors 71 are connected each in parallel to the DC voltage source DVS. The switching supply circuit SS3 is also a step-down type switching supply circuit.

In the switching supply circuit SS3, the chip electronic component EC1 is connected in series to each of the first capacitors 71. The first terminal electrode 11 of the chip electronic component EC1 is connected to one of the first capacitors 71. The third terminal electrode 15 of the chip electronic component EC1 is connected to the other first capacitor 71. The second terminal electrode 13 of the chip electronic component EC1 is connected to the negative electrode of the DC voltage source DVS.

In the present embodiment, the current path consisting of the first terminal electrode 11 (or the third terminal electrode 15), the internal conductors 7, and the second terminal electrode 13 is inserted in a loop consisting of the first capacitors 71, the first transistor 73, and the second transistor 75. For this reason, the loop consisting of the first capacitors 71, the first transistor 73, and the second transistor 75 has the impedance high enough to suppress occurrence of resonance in the loop. As a consequence, the switching supply circuit SS3 can also suppress occurrence of electromagnetic noise.

In order to adjust the impedance of the loop consisting of the first capacitors 71, the first transistor 73, and the second transistor 75, as shown in FIG. 43, the fourth terminal electrode 17 of the chip electronic component EC1 may be connected to the negative electrode of the DC voltage source DVS. In this case, the number of current paths from the chip electronic component EC1 is increased and, for this reason, the impedance of the loop consisting of the first capacitors 71, first transistor 73, and second transistor 75 becomes lower in the switching supply circuit SS3 shown in FIG. 43 than in the switching supply circuit SS3 shown in FIG. 42.

In the present embodiment, as described above, the switching supply circuit SS3 is provided with the chip electronic component EC1. The chip electronic component EC1 has at least two current paths as described above. For this reason, control of impedance is performed readily and over a wide range in the switching supply circuit SS3, without increase in the number of parts.

The above described the preferred embodiments of the present invention, but it should be noted that the present invention does not always have to be limited to the above-described embodiments and can be modified in many ways without departing from the scope and spirit of the invention.

The chip electronic components EC1-EC6 are the so-called multilayer chip beads in which the internal conductors 7, 31, 33, 41, 43, 61, 63 are arranged in the element body consisting of the stack of insulator layers 5 containing the ferrite material, but the present invention is not limited to this configuration. For example, the chip electronic components EC1-EC6 may be chip electronic components in which the internal conductors 7, 31, 33, 41, 43, 61, 63 are arranged in a resin containing a ferrite material (ferrite resin).

The chip electronic components EC1-EC4 are provided with the four terminal electrodes 11-17, but the present invention is not limited to this configuration. The chip electronic components EC1-EC4 may be provided with three terminal electrodes (e.g., the first to third terminal electrodes 11-15) or with five or more terminal electrodes. In the chip electronic components EC1-EC6, the number of laminated insulator layers 5, and the number and shape of laminated internal conductors 7, 31, 33, 41, 43, 61, 63 are not limited to those in the above-described embodiments and modification examples.

In the ninth to eleventh embodiments, the chip electronic component EC2, EC3, or EC4 may be inserted instead of the chip electronic component EC1.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A chip electronic component comprising:
an element body containing a ferrite material;
a first terminal electrode, a second terminal electrode, and a third terminal electrode arranged on a surface of the element body; and
an internal conductor arranged in the element body and electrically connected to the first terminal electrode, the second terminal electrode, and the third terminal electrode,
wherein an impedance of a current path through the internal conductor between the first terminal electrode and the second terminal electrode is different from an impedance of a current path through the internal conductor between the first terminal electrode and the third terminal electrode.

2. The chip electronic component according to claim 1,
wherein the internal conductor is physically connected to the first terminal electrode, the second terminal electrode, and the third terminal electrode.

3. The chip electronic component according to claim 2,
wherein in the internal conductor, a length of the current path between the first terminal electrode and the second terminal electrode is different from a length of the current path between the first terminal electrode and the third terminal electrode.

4. The chip electronic component according to claim 2,
wherein in the internal conductor, a width of the current path between the first terminal electrode and the second terminal electrode is different from a width of the current path between the first terminal electrode and the third terminal electrode.

5. The chip electronic component according to claim 1,
wherein the internal conductor comprises a first internal conductor physically connected to the first terminal electrode and the second terminal electrode, and a second internal conductor physically connected to the second terminal electrode and the third terminal electrode, and
wherein the first terminal electrode and the third terminal electrode are electrically connected through the first and second internal conductors and the second terminal electrode.

6. The chip electronic component according to claim 1,
wherein the element body has first and second principal faces of a nearly square shape opposed to each other, first and second side faces extending in a first-side direction of the first and second principal faces so as to connect the first and second principal faces, and opposed to each other, and third and fourth side faces extending in a second-side direction perpendicular to the first-side direction of the first and second principal faces so as to connect the first and second principal faces, and opposed to each other, and
wherein the first terminal electrode, the second terminal electrode, and the third terminal electrode are arranged respectively on different side faces out of the first to fourth side faces.

7. The chip electronic component according to claim 1,
wherein the element body has first and second principal faces of a nearly rectangular shape opposed to each other, first and second side faces extending in a long-side direction of the first and second principal faces so as to connect the first and second principal faces, and opposed to each other, and third and fourth side faces extending in a short-side direction of the first and second principal faces so as to connect the first and second principal faces, and opposed to each other, and
wherein the first terminal electrode, the second terminal electrode, and the third terminal electrode are arranged respectively on different side faces out of the first to fourth side faces.

8. The chip electronic component according to claim 1,
wherein the first terminal electrode, the second terminal electrode, and the third terminal electrode are arranged on the same face of the element body.

9. A mounted structure of a chip electronic component, comprising:
the chip electronic component as set forth in claim 1, and a capacitor,
wherein the chip electronic component and the capacitor are connected in series so that the first terminal electrode of the chip electronic component is located on the capacitor side.

10. A mounted structure of a chip electronic component in which the chip electronic component is inserted in a circuit,
wherein the chip electronic component comprises an element body containing a ferrite material, and an internal conductor arranged in the element body,
wherein the circuit comprises a first line, a second line, and a third line electrically connected to the internal conductor, and
wherein an impedance of a current path through the internal conductor between the first line and the second line is different from an impedance of a current path through the internal conductor between the first line and the third line.

11. The mounted structure of the chip electronic component according to claim 10,
wherein the chip electronic component further comprises a first terminal electrode, a second terminal electrode, and a third terminal electrode physically connected to the internal conductor,
wherein the first terminal electrode is physically connected to the first line,
wherein the second terminal electrode is physically connected to the second line, and
wherein the third terminal electrode is physically connected to the third line.

12. The mounted structure of the chip electronic component according to claim 11,
wherein in the internal conductor, a length of a current path between the first terminal electrode and the second terminal electrode is different from a length of a current path between the first terminal electrode and the third terminal electrode.

13. The mounted structure of the chip electronic component according to claim 11,
wherein in the internal conductor, a width of a current path between the first terminal electrode and the second terminal electrode is different from a width of a current path between the first terminal electrode and the third terminal electrode.

14. The mounted structure of the chip electronic component according to claim 11,
wherein the internal conductor comprises a first internal conductor physically connected to the first terminal electrode and the second terminal electrode, and a second internal conductor physically connected to the second terminal electrode and the third terminal electrode, and
wherein the first terminal electrode and the third terminal electrode are electrically connected through the first and second internal conductors and the second terminal electrode.

15. The mounted structure of the chip electronic component according to claim 10,
wherein the chip electronic component further comprises a first terminal electrode, a second terminal electrode, a third terminal electrode, and a fourth terminal electrode arranged on a surface of the element body,
wherein the internal conductor comprises a first internal conductor physically connected to the first terminal electrode and the second terminal electrode, and a second internal conductor physically connected to the third terminal electrode and the fourth terminal electrode,
wherein the first terminal electrode is physically connected to the first line,
wherein the second and third terminal electrodes are physically connected to the second line, and
wherein the fourth terminal electrode is physically connected to the third line.

16. A switching supply circuit comprising:
a first capacitor connected in parallel to a DC voltage source;
a first transistor connected to a positive electrode of the DC voltage source;
a second transistor connected between the first transistor and a negative electrode of the DC voltage source and brought into a conductive state, alternating with the first transistor;
the chip electronic component as set forth in claim 1, which is inserted at a midpoint between the first transistor and the second transistor;
an inductor one end of which is connected to the chip electronic component; and
a second capacitor one end of which is connected to the other end of the inductor and the other end of which is connected to the negative electrode of the DC voltage source,
wherein the first transistor is connected to the first terminal electrode of the chip electronic component,
wherein the second transistor is connected to the third terminal electrode of the chip electronic component,
wherein the one end of the inductor is connected to the second terminal electrode of the chip electronic component, and
wherein the impedance of the current path through the internal conductor between the first terminal electrode and the third terminal electrode is higher than the impedance of the current path through the internal conductor between the first terminal electrode and the second terminal electrode.

17. A switching supply circuit comprising:
a first capacitor connected in parallel to a DC voltage source;
a first transistor connected to a positive electrode of the DC voltage source;
a second transistor connected between the first transistor and a negative electrode of the DC voltage source and brought into a conductive state, alternating with the first transistor;
a chip electronic component inserted at a midpoint between the first transistor and the second transistor;
an inductor one end of which is connected to the chip electronic component; and
a second capacitor one end of which is connected to the other end of the inductor and the other end of which is connected to the negative electrode of the DC voltage source,
wherein the chip electronic component has:
an element body containing a ferrite material;
a first terminal electrode, a second terminal electrode, a third terminal electrode, and a fourth terminal electrode arranged on a surface of the element body;
a first internal conductor arranged in the element body and physically connected to the first terminal electrode and the second terminal electrode; and
a second internal conductor arranged in the element body and physically connected to the third terminal electrode and the fourth terminal electrode,
wherein the first transistor is connected to the first terminal electrode of the chip electronic component,
wherein the second transistor is connected to the fourth terminal electrode of the chip electronic component, and
wherein the one end of the inductor is connected to the second and third terminal electrodes of the chip electronic component.

18. A switching supply circuit comprising:
a first capacitor connected in parallel to a DC voltage source;
the chip electronic component as set forth in claim 1, which is inserted in series to the first capacitor;
a first transistor connected to a positive electrode of the DC voltage source;
a second transistor connected between the first transistor and a negative electrode of the DC voltage source and brought into a conductive state, alternating with the first transistor;
an inductor one end of which is connected to a midpoint between the first transistor and the second transistor; and
a second capacitor one end of which is connected to the other end of the inductor and the other end of which is connected to the negative electrode of the DC voltage source,
wherein the first capacitor is connected to the first terminal electrode of the chip electronic component, and
wherein at least one terminal electrode out of the second and third terminal electrodes of the chip electronic component is connected to the negative electrode of the DC voltage source.
